(19) United States
(12) Patent Application Publication
(10) Pub. No.: US 2025/0167757 A1
(43) Pub. Date: May 22, 2025

(54) ACOUSTIC WAVE DEVICE AND FILTER DEVICE

(71) Applicant: Murata Manufacturing Co., Ltd., Nagaokakyo-shi (JP)

(72) Inventor: Katsuya DAIMON, Nagaokakyo-shi (JP)

(21) Appl. No.: 19/030,233

(22) Filed: Jan. 17, 2025

Related U.S. Application Data
(63) Continuation of application No. PCT/JP2023/030816, filed on Aug. 25, 2023.
(60) Provisional application No. 63/401,252, filed on Aug. 26, 2022.

(51) Int. Cl. H03H 9/02; H03H 9/17; H03H 9/56

(52) U.S. Cl. CPC H03H 9/02086; H03H 9/02015; H03H 9/175; H03H 9/568

(57) ABSTRACT

An acoustic wave device includes a piezoelectric substrate including a support including a support substrate and a piezoelectric film on the support and including a piezoelectric layer, and an IDT electrode on the piezoelectric layer and including first and second busbars and first and second electrode fingers. An acoustic reflection portion is in the support overlapping the IDT electrode. When a thickness of the piezoelectric film is d and a center-to-center distance between the adjacent electrode fingers is p, d/p is about 0.5 or smaller. When viewed in an electrode finger orthogonal direction, a region in which the adjacent electrode fingers overlap each other is an intersecting region. A region between the intersecting region and the first and second busbars includes first and second gap regions. The intersecting region includes a central region and first and second edge regions extending across the central region in the electrode finger extending direction.

### CROSS REFERENCE TO RELATED APPLICATIONS

This application claims the benefit of priority to Provisional Application No. 63/401,252 filed on Aug. 26, 2022 and is a Continuation application of PCT Application No. PCT/JP2023/030816 filed on Aug. 25, 2023. The entire contents of each application are hereby incorporated herein by reference.

### BACKGROUND OF THE INVENTION

### 1. Field of the Invention

The present invention relates to acoustic wave devices and filter devices.

### 2. Description of the Related Art

In the related art, an acoustic wave device has been widely used for a filter or the like of a mobile phone. In recent years, as disclosed in U.S. Pat. No. 10,491,192, an acoustic wave device using a bulk wave in a thickness shear mode has been proposed. In the acoustic wave device, a piezoelectric layer is provided on a support body. A pair of electrodes are provided on the piezoelectric layer. The pair of electrodes face each other on the piezoelectric layer, and are connected to mutually different potentials. An alternating current (AC) voltage is applied between the electrodes to excite the bulk wave in the thickness shear mode.

Japanese Unexamined Patent Application Publication No. 2019-080093 discloses an example of an acoustic wave device using a piston mode. In this acoustic wave device, an interdigital transducer (IDT) electrode is provided on a piezoelectric film. A region in which the electrode fingers of the IDT electrode overlap each other in an acoustic wave propagation direction is defined as an intersecting region. A pair of gap regions are provided in a region between the intersecting region and a pair of busbars of the IDT electrode. The intersecting region includes a central region and a pair of edge regions. The pair of edge regions face each other across the central region in a direction in which a plurality of electrode fingers extend.

Japanese Unexamined Patent Application Publication No. 2019-080093 discloses an example in which a mass addition film is extending over the edge region, the gap region, and the busbar. In this example, the piston mode is established by forming a plurality of regions having different acoustic velocities in the direction in which the plurality of electrode fingers extend. In this manner, a transverse mode is suppressed.

### SUMMARY OF THE INVENTION

The present inventor has focused on a discovery that deterioration in a loss can be suppressed by providing a mass addition film in an edge region and a gap region in an acoustic wave device using a bulk wave in a thickness shear mode, but unnecessary waves are generated in the vicinity of a resonant frequency and in the vicinity of an anti-resonant frequency.

Example embodiments of the present invention provide acoustic wave devices and filter devices each of which can reduce or prevent unnecessary waves in a vicinity of a resonant frequency or in a vicinity of an anti-resonant frequency, even when a mass addition film is provided in an edge region and a gap region.

An acoustic wave device according to an example embodiment of the present invention a piezoelectric substrate including a support including a support substrate, and a piezoelectric film provided on the support and including a piezoelectric layer including lithium niobate, and an IDT electrode provided on the piezoelectric layer and including a pair of busbars and a plurality of electrode fingers. An acoustic reflection portion is at a position in the support overlapping the IDT electrode in plan view in a multilayer direction of the support and the piezoelectric film. When a thickness of the piezoelectric film is defined as d and a center-to-center distance between the electrode fingers adjacent to each other is defined as p, d/p is about 0.5 or smaller. Some electrode fingers of the plurality of electrode fingers are connected to one of the busbars of the IDT electrode, remaining electrode fingers of the plurality of electrode fingers are connected to an other of the busbars. The plurality of electrode fingers connected to the busbar and the plurality of electrode fingers connected to the other busbar are interdigitated with each other. When a direction in which the plurality of electrode fingers extend is defined as an electrode finger extending direction, and a direction orthogonal to the electrode finger extending direction is defined as an electrode finger orthogonal direction, when viewed in the electrode finger orthogonal direction, a region in which the electrode fingers adjacent to each other overlap each other is an intersecting region, and a region located between the intersecting region and the pair of busbars is a pair of gap regions. The intersecting region includes a central region and a pair of edge regions extending across the central region in the electrode finger extending direction. The acoustic wave device further includes a strip-shaped mass addition film provided in at least one gap region of the pair of gap regions and continuously extending to overlap the plurality of electrode fingers and a region between the electrode fingers in plan view, and a plurality of granular mass addition films extending over the gap region in which the strip-shaped mass addition film is provided and one of the edge regions adjacent to the gap region and not overlapping at least a portion in at least a region between the electrode fingers adjacent to each other in plan view.

A filter device according to an example embodiment of the present invention includes a plurality of acoustic wave resonators including at least one series arm resonator and at least one parallel arm resonator. In the filter device, at least one of the acoustic wave resonators of the series arm resonator and the parallel arm resonator is the acoustic wave device according to the above-described example embodiment of the present invention.

According to example embodiments of the present invention, it is possible to provide acoustic wave devices and filter devices each of which can reduce or prevent unnecessary waves in the vicinity of a resonant frequency or in the vicinity of an anti-resonant frequency, even when a mass addition film is provided in an edge region and a gap region.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic cross-sectional view taken along line I-I in FIG. 1.

FIG. 3 is a schematic plan view of an acoustic wave device of a first comparative example.

FIG. 4 is a schematic plan view of an acoustic wave device of a second comparative example.

FIG. 5 is a schematic plan view for describing first to third dimensions.

FIG. 6 is a diagram showing a return loss in the first example embodiment, the first comparative example, and the second comparative example of the present invention when a material of a strip-shaped mass addition film and a granular mass addition film is SiO₂.

FIG. 7 is a diagram showing excitation intensity of unnecessary waves in the first comparative example.

FIG. 8 is a diagram showing a return loss in the first example embodiment of the present invention, the first comparative example, and the second comparative example when the material of the strip-shaped mass addition film and the granular mass addition film is Ta₂O₅.

FIG. 9 is a schematic plan view of an acoustic wave device according to a first modification example of the first example embodiment of the present invention.

FIG. 10 is a schematic plan view of an acoustic wave device according to a second modification example of the first example embodiment of the present invention.

FIG. 11 is a schematic plan view of an acoustic wave device according to a second example embodiment of the present invention.

FIG. 12 is a schematic plan view of an acoustic wave device according to a third example embodiment of the present invention.

FIG. 13 is a schematic plan view of an acoustic wave device according to a fourth example embodiment of the present invention.

FIG. 14 is a schematic plan view of an acoustic wave device according to a fifth example embodiment of the present invention.

FIG. 15 is a schematic plan view of an acoustic wave device according to a sixth example embodiment of the present invention.

FIG. 16 is a schematic plan view of an acoustic wave device according to a seventh example embodiment of the present invention.

FIG. 17 is a schematic plan view of an acoustic wave device according to a modification example of the seventh example embodiment of the present invention.

FIG. 18 is a circuit diagram of a filter device according to an eighth example embodiment of the present invention.

FIG. 19 is a schematic plan view of a second acoustic wave resonator according to a ninth example embodiment of the present invention.

FIG. 20 is a schematic plan view of a third acoustic wave resonator according to the ninth example embodiment of the present invention.

FIG. 21 is a schematic plan view of a fourth acoustic wave resonator according to the ninth example embodiment of the present invention.

FIG. 22 is a schematic plan view of a fifth acoustic wave resonator according to the ninth example embodiment of the present invention.

FIG. 23A is a schematic perspective view showing an appearance of an acoustic wave device using a bulk wave in a thickness shear mode, and FIG. 23B is a plan view showing an electrode structure on a piezoelectric layer.

FIG. 24 is a cross-sectional view of a portion taken along line A-A in FIG. 23A.

FIG. 25A is a schematic elevational cross-sectional view for describing a Lamb wave propagating through a piezoelectric film of the acoustic wave device, and FIG. 25B is a schematic elevational cross-sectional view for describing the bulk wave in the thickness shear mode propagating through the piezoelectric film in the acoustic wave device.

FIG. 26 is a diagram showing an amplitude direction of the bulk wave in the thickness shear mode.

FIG. 27 is a diagram showing resonance characteristics of the acoustic wave device using the bulk wave in the thickness shear mode.

FIG. 28 is a diagram showing a relationship between d/p and a fractional bandwidth as a resonator when a center-to-center distance between adjacent electrodes is defined as p and a thickness of a piezoelectric layer is defined as d.

FIG. 29 is a plan view of an acoustic wave device using a bulk wave in a thickness shear mode.

FIG. 30 is a diagram showing resonance characteristics of an acoustic wave device of a reference example in which spurious appears.

FIG. 31 is a diagram showing a relationship between a fractional bandwidth and a phase rotation amount of impedance of the spurious standardized at 180 degrees as a magnitude of the spurious.

FIG. 32 is a diagram showing a relationship between d/2p and a metallization ratio MR.

FIG. 33 is a diagram showing a map of the fractional bandwidth with respect to Euler angles (0°, θ, ψ) of LiNbO₃ when d/p is infinitely close to 0.

FIG. 34 is an elevational cross-sectional view of an acoustic wave device including an acoustic multilayer film.

### DETAILED DESCRIPTION OF THE EXAMPLE EMBODIMENTS

Hereinafter, the present invention will be clearly understood by describing specific example embodiments of the present invention with reference to the drawings.

Each example embodiment described in the present specification is merely an example, and configurations can be partially replaced or combined with each other between different example embodiments.

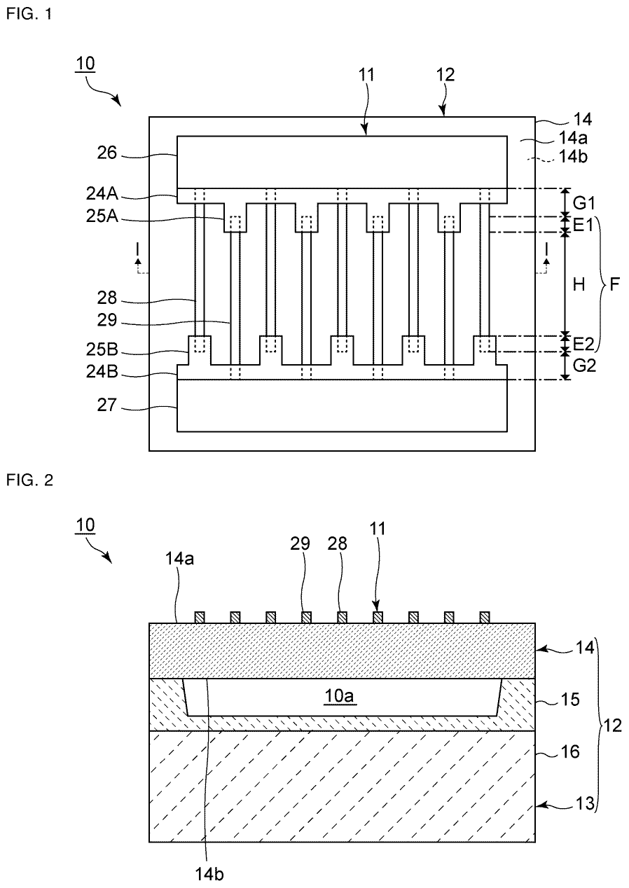

FIG. 1 is a schematic plan view of an acoustic wave device according to a first example embodiment of the present invention. FIG. 2 is a schematic cross-sectional view taken along line I-I in FIG. 1.

As shown in FIG. 1, an acoustic wave device 10 includes a piezoelectric substrate 12 and an IDT electrode 11. The piezoelectric substrate 12 is a substrate having piezoelectricity. As shown in FIG. 2, the piezoelectric substrate 12 includes a support 13 and a piezoelectric layer 14 serving as a piezoelectric film. The piezoelectric layer 14 is a layer having a piezoelectric body. On the other hand, in the present specification, the piezoelectric film is a film having piezoelectricity, and does not necessarily indicate a film including the piezoelectric body. However, in the present example embodiment, the piezoelectric film is the piezoelectric layer 14 having a single layer, and is a film including the piezoelectric body. In an example embodiment of the present invention, the piezoelectric film may be a laminated film including the piezoelectric layer 14. In the present example embodiment, the support 13 includes a support substrate 16 and an insulating layer 15. The insulating layer 15 is provided on the support substrate 16. The piezoelectric layer 14 is provided on the insulating layer 15. The support 13 may include only the support substrate 16.

The piezoelectric layer 14 includes a first main surface 14a and a second main surface 14b. The first main surface 14a and the second main surface 14b face each other. Out of the first main surface 14a and the second main surface 14b, the second main surface 14b is located on the support 13 side.

As a material of the support substrate 16, for example, a semiconductor such as silicon, ceramics such as aluminum oxide, or the like can be used. As a material of the insulating layer 15, an appropriate dielectric such as silicon oxide or tantalum oxide can be used. For example, the piezoelectric layer 14 is formed of lithium niobate such as LiNbO₃. In the present specification, a fact that a certain structural element or portion is formed of a certain material includes a case where a trace amount of impurities is included to the extent that the electrical characteristics of the acoustic wave device do not significantly deteriorate.

As shown in FIG. 2, a recess portion is provided in the insulating layer 15. The piezoelectric layer 14 serving as the piezoelectric film is provided on the insulating layer 15 to close the recess portion. In this manner, a hollow portion is provided. The hollow portion includes a cavity portion 10a. In the present example embodiment, the support 13 and the piezoelectric film are disposed such that a portion of the support 13 and a portion of the piezoelectric film face each other across the cavity portion 10a. The recess portion in the support 13 may extend over the insulating layer 15 and the support substrate 16. Alternatively, the recess portion provided only in the support substrate 16 may be closed by the insulating layer 15. The recess portion may be provided in the piezoelectric layer 14, for example. The cavity portion 10a may be a through hole provided in the support 13.

The IDT electrode 11 is provided on the first main surface 14a of the piezoelectric layer 14. At least a portion of the IDT electrode 11 overlaps the cavity portion 10a of the support 13 in plan view. In the present specification, description of “a plan view” means that an object is viewed in a multilayer direction of the support 13 and the piezoelectric film from a direction corresponding to an upper side in FIG. 2. In FIG. 2, for example, the piezoelectric layer 14 side is an upper side out of the support substrate 16 side and the piezoelectric layer 14 side. Furthermore, in the present specification, a plan view is synonymous with viewing from a main surface facing direction. The main surface facing direction is a direction in which the first main surface 14a and the second main surface 14b of the piezoelectric layer 14 face each other. More specifically, for example, the main surface facing direction is a direction normal to the first main surface 14a.

As shown in FIG. 1, the IDT electrode 11 includes a pair of busbars and a plurality of electrode fingers. Specifically, the pair of busbars are a first busbar 26 and a second busbar 27. The first busbar 26 and the second busbar 27 face each other. Specifically, the plurality of electrode fingers are a plurality of first electrode fingers 28 and a plurality of second electrode fingers 29. Each one end of the plurality of first electrode fingers 28 is connected to the first busbar 26. Each one end of the plurality of second electrode fingers 29 is connected to the second busbar 27. The plurality of first electrode fingers 28 and the plurality of second electrode fingers 29 are interdigitated with each other. The IDT electrode 11 may include a single metal film, or may include a laminated metal film.

Hereinafter, the first busbar 26 and the second busbar 27 may be collectively referred to as the busbars. The first electrode finger 28 and the second electrode finger 29 may be collectively referred to simply as the electrode fingers. A direction in which the plurality of electrode fingers extend will be referred to as an electrode finger extending direction, and a direction orthogonal to the electrode finger extending direction will be referred to as an electrode finger orthogonal direction. When a direction in which adjacent electrode fingers face each other is defined as an electrode finger facing direction, the electrode finger orthogonal direction and the electrode finger facing direction are parallel to each other.

When viewed in the electrode finger orthogonal direction, a region in which the adjacent electrode fingers overlap each other is an intersecting region F. The intersecting region F includes a central region H and a pair of edge regions. Specifically, the pair of edge regions are a first edge region E1 and a second edge region E2. The first edge region E1 and the second edge region E2 extend across the central region H in the electrode finger extending direction. The first edge region E1 is located on the first busbar 26 side. The second edge region E2 is located on the second busbar 27 side.

A region located between the intersecting region F and the pair of busbars is a pair of gap regions. Specifically, the pair of gap regions are a first gap region G1 and a second gap region G2. The first gap region G1 is located between the first busbar 26 and the first edge region E1. The second gap region G2 is located between the second busbar 27 and the second edge region E2.

The acoustic wave device 10 is an acoustic wave resonator configured such that a bulk wave in a thickness shear mode can be used. More specifically, in the acoustic wave device 10, when a thickness of the piezoelectric film is defined as d and a center-to-center distance between the adjacent electrode fingers is defined as p, d/p is about 0.5 or smaller, for example. In this manner, the bulk wave in the thickness shear mode is suitably excited. In the present example embodiment, the thickness d is the thickness of the piezoelectric layer 14.

An excitation region is a region in which the electrode fingers adjacent to each other overlap each other when viewed in the electrode finger orthogonal direction, and is a center-to-center region of the electrode fingers adjacent to each other. That is, the intersecting region F includes a plurality of the excitation regions. In each excitation region, the bulk wave in the thickness shear mode is excited. The intersecting region F, the excitation region, and the pair of gap regions are regions of the piezoelectric layer 14 which are defined based on a configuration of the IDT electrode 11. However, the intersecting region F and the pair of gap regions can be referred to as regions of the IDT electrode 11 to show the configuration of the IDT electrode 11.

The cavity portion 10a of the support 13 shown in FIG. 2 is an acoustic reflection portion. The acoustic reflection portion can effectively confine energy of an acoustic wave on the piezoelectric layer 14 side. As the acoustic reflection portion, an acoustic multilayer film (to be described later) may be provided. For example, the acoustic reflection film may be provided on a surface of the support.

In the present specification, the first edge region E1 and the second edge region E2 may be collectively referred to as the edge regions. Similarly, the first gap region G1 and the second gap region G2 may be collectively referred to as the gap regions. Furthermore, in the following description, when a structural element or portion overlaps the edge region in plan view, it may be simply described that the structural element or portion is provided in the edge region. For example, even when the structural element or portion is not directly provided on the piezoelectric layer 14, it may be described that the structural element or portion is provided in the edge region. The same applies to the gap region.

As shown in FIG. 1, the acoustic wave device 10 includes a pair of strip-shaped mass addition films. The strip-shaped mass addition film is a mass addition film having a strip shape. Specifically, the pair of strip-shaped mass addition films are a first strip-shaped mass addition film 24A and a second strip-shaped mass addition film 24B. The first strip-shaped mass addition film 24A is provided in the first gap region G1. The second strip-shaped mass addition film 24B is provided in the second gap region G2.

The acoustic wave device 10 includes a plurality of granular mass addition films. The granular mass addition film is a mass addition film having a smaller dimension in the electrode finger orthogonal direction than the strip-shaped mass addition film. Specifically, the plurality of granular mass addition films are a plurality of first granular mass addition films 25A and a plurality of second granular mass addition films 25B.

The plurality of first granular mass addition films 25A are extending over the first gap region G1 and the first edge region E1. The plurality of first granular mass addition films 25A are aligned in the electrode finger orthogonal direction. The plurality of second granular mass addition films 25B are extending over the second gap region G2 and the second edge region E2. The plurality of second granular mass addition films 25B are aligned in the electrode finger orthogonal direction.

In the present specification, the first strip-shaped mass addition film 24A and the second strip-shaped mass addition film 24B may be collectively referred to as the strip-shaped mass addition films. The first granular mass addition film 25A and the second granular mass addition film 25B may be collectively referred to as the granular mass addition films. Hereinafter, configurations of the strip-shaped mass addition film and the granular mass addition film will be described in more detail.

The first strip-shaped mass addition film 24A is provided on the first main surface 14a of the piezoelectric layer 14 to cover the plurality of electrode fingers. The first strip-shaped mass addition film 24A is continuously provided to overlap the plurality of first electrode fingers 28, the plurality of second electrode fingers 29, and the region between the electrode fingers in plan view. The second strip-shaped mass addition film 24B is also continuously provided to overlap the plurality of first electrode fingers 28, the plurality of second electrode fingers 29, and the region between the electrode fingers in plan view.

The first strip-shaped mass addition film 24A is provided in a portion of the first gap region G1. More specifically, the first strip-shaped mass addition film 24A extends to an end edge portion of the first gap region G1 on the first busbar 26 side in the electrode finger extending direction. The second strip-shaped mass addition film 24B is provided in a portion of the second gap region G2. The second strip-shaped mass addition film 24B extends to an end edge portion of the second gap region G2 on the second busbar 27 side in the electrode finger extending direction. However, disposition of the first strip-shaped mass addition film 24A and the second strip-shaped mass addition film 24B is not limited to the above-described configuration.

The plurality of first granular mass addition films 25A and the plurality of second granular mass addition films 25B are provided in a period of every other electrode finger in the electrode finger orthogonal direction. Specifically, each of the plurality of first granular mass addition films 25A overlaps the second electrode finger 29 in plan view. The plurality of first granular mass addition films 25A do not overlap the first electrode fingers 28 in plan view. On the other hand, each of the plurality of second granular mass addition films 25B overlaps the first electrode finger 28 in plan view. The plurality of second granular mass addition films 25B do not overlap the second electrode fingers 29 in plan view.

The period in which the plurality of first granular mass addition films 25A and the plurality of second granular mass addition films 25B are provided is not limited to the above-described configuration. For example, the plurality of first granular mass addition films 25A and the plurality of second granular mass addition films 25B may overlap both the first electrode finger 28 and the second electrode finger 29 in plan view.

Each of the first granular mass addition films 25A overlaps one electrode finger in plan view. Specifically, each of the first granular mass addition films 25A is extending over the first main surface 14a of the piezoelectric layer 14 and one electrode finger. The first granular mass addition film 25A is not extending over the plurality of electrode fingers. In this way, each of the first granular mass addition films 25A is provided not to overlap a portion between the electrode fingers in plan view.

Each of the second granular mass addition films 25B is also extending over the first main surface 14a of the piezoelectric layer 14 and one electrode finger. Each of the second granular mass addition films 25B is not extending over the plurality of electrode fingers. Each of the second granular mass addition films 25B is provided not to overlap a portion between the electrode fingers in plan view.

The granular mass addition film may overlap one or more electrode fingers in plan view. Alternatively, the granular mass addition film does not necessarily overlap the electrode finger in plan view. In this case, it is preferable that a portion of the granular mass addition film located in the gap region is located on an extension line of the electrode finger in plan view.

The IDT electrode 11 includes a plurality of pairs of first and second electrode fingers 28 and 29. Therefore, the acoustic wave device 10 includes a plurality of regions between the electrode fingers. In an example embodiment of the present invention, the granular mass addition film may be provided not to overlap at least a portion in at least a region between the adjacent electrode fingers in plan view.

In the present example embodiment, the first strip-shaped mass addition film 24A, the plurality of first granular mass addition films 25A, the second strip-shaped mass addition film 24B, and the plurality of second granular mass addition films 25B include a dielectric.

The first strip-shaped mass addition film 24A and the plurality of first granular mass addition films 25A are integrally formed of the same material. The second strip-shaped mass addition film 24B and the plurality of second granular mass addition films 25B are integrally formed of the same material. However, the first strip-shaped mass addition film 24A and the plurality of first granular mass addition films 25A may be individually provided. The second strip-shaped mass addition film 24B and the plurality of second granular mass addition films 25B may be individually provided.

The acoustic wave device 10 may include at least one of the first strip-shaped mass addition film 24A and the second strip-shaped mass addition film 24B. In other words, the strip-shaped mass addition film may be provided in at least one of the pair of gap regions.

The acoustic wave device 10 may include the plurality of first granular mass addition films 25A or the plurality of second granular mass addition films 25B. Alternatively, the acoustic wave device 10 may include both the plurality of first granular mass addition films 25A and the plurality of second granular mass addition films 25B. The plurality of granular mass addition films may be provided in the gap region in which the strip-shaped mass addition film is provided and the edge region adjacent to the gap region. For example, when the first strip-shaped mass addition film 24A is provided, the plurality of first granular mass addition films 25A may be provided. When the second strip-shaped mass addition film 24B is provided, the plurality of second granular mass addition films 25B may be provided.

According to features of the present example embodiment, the strip-shaped mass addition film is provided in the gap region, and the plurality of granular mass addition films are provided in the gap region in which the strip-shaped mass addition film is provided and the edge region adjacent to the gap region. Since the plurality of granular mass addition films are provided in the edge region, a transverse mode can be suppressed. In addition, since both the strip-shaped mass addition film and the granular mass addition film are provided, unnecessary waves generated by providing the mass addition film can be reduced or prevented.

The unnecessary waves caused by providing the mass addition film are generated in the vicinity of the resonant frequency or in the vicinity of the anti-resonant frequency. In the present example embodiment, even when the mass addition film is provided in the edge region and the gap region, the unnecessary waves can be reduced or prevented in the vicinity of the resonant frequency or in the vicinity of the anti-resonant frequency. Details of this advantageous effect will be described below by comparing the present example embodiment with a first comparative example and a second comparative example.

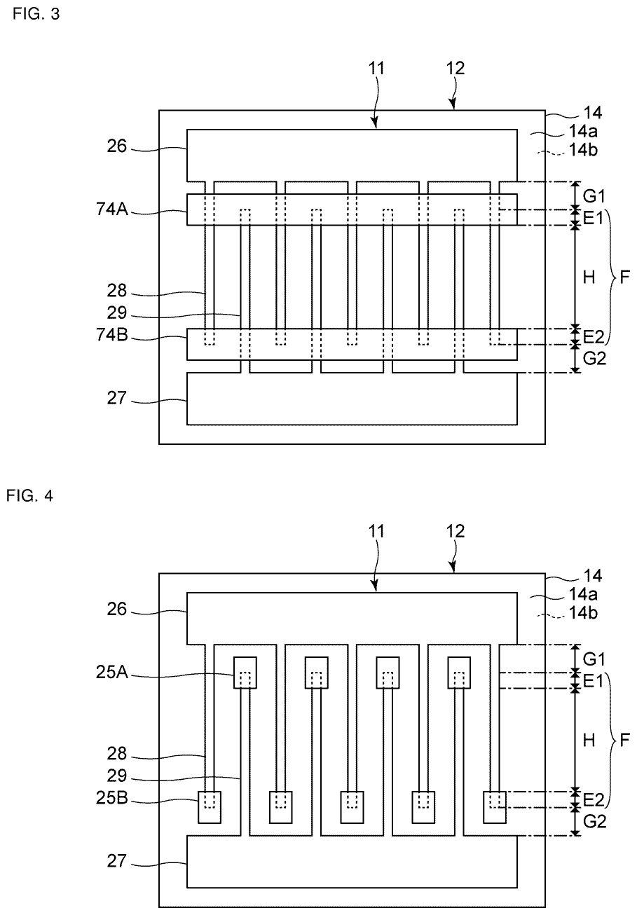

As shown in FIG. 3, the first comparative example is different from the first example embodiment in that the pair of strip-shaped mass addition films are extending over the pair of gap regions and the pair of edge regions and the granular mass addition film is not provided. Specifically, in the first comparative example, a first strip-shaped mass addition film 74A is extending over the first gap region G1 and the first edge region E1. A second strip-shaped mass addition film 74B is extending over the second gap region G2 and the second edge region E2. Each of the strip-shaped mass addition films is continuously provided to overlap the plurality of electrode fingers and the region between the electrode fingers in plan view.

As shown in FIG. 4, the second comparative example is different from the first example embodiment in that the strip-shaped mass addition film is not provided. In the second comparative example, the plurality of first granular mass addition films 25A are extending over the first gap region G1 and the first edge region E1. The plurality of second granular mass addition films 25B are extending over the second gap region G2 and the second edge region E2.

A return loss is measured in each of the acoustic wave device 10 having the configuration of the first example embodiment, the acoustic wave device of the first comparative example, and the acoustic wave device of the second comparative example. In the acoustic wave devices, SiO₂ is used as a material of the strip-shaped mass addition film and the granular mass addition film.

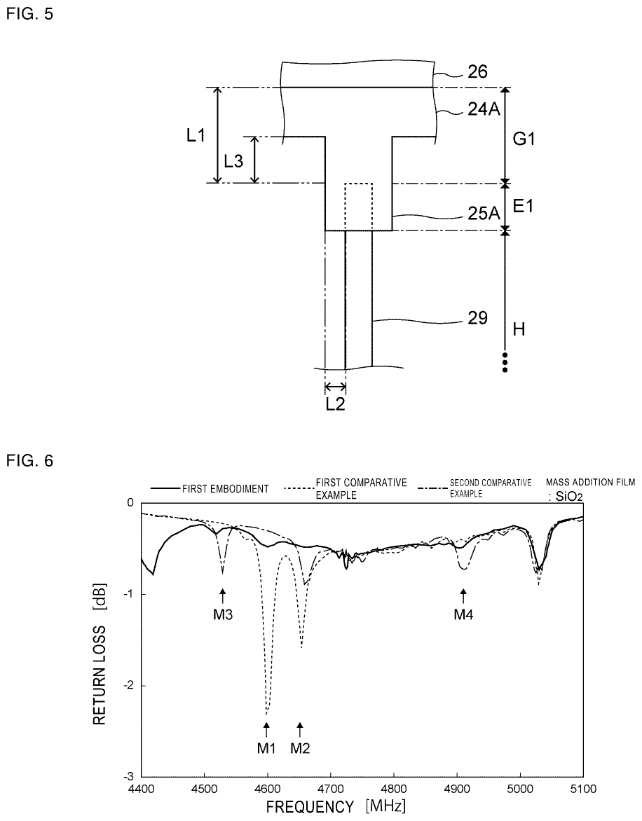

In the first example embodiment related to the comparison, a first dimension L1, a second dimension L2, and a third dimension L3 which are shown in FIG. 5 are as follows.

The first dimension L1 is a dimension of the gap region in the electrode finger extending direction. The second dimension L2 is a dimension of the granular mass addition film of a portion provided in a region between the electrode fingers in the electrode finger orthogonal direction. The third dimension L3 is a dimension of the granular mass addition film of a portion provided in the gap region in the electrode finger extending direction. In the first example embodiment related to the comparison, the first dimension L1 is set to about 7 μm, the second dimension L2 is set to about 0.5 μm, and the third dimension L3 is set to about 2 μm, for example. In the first example embodiment related to the comparison, the thickness of the strip-shaped mass addition film and the granular mass addition film is set to about 30 nm, for example.

FIG. 6 is a diagram showing a return loss in the first example embodiment, the first comparative example, and the second comparative example when the material of the strip-shaped mass addition film and the granular mass addition film is SiO₂.

As shown in FIG. 6, in the first comparative example, the unnecessary waves are generated in the vicinity of the frequency indicated by an arrow M1 and an arrow M2. In the second comparative example, the unnecessary waves are generated in the vicinity of the frequency indicated by the arrow M2, in the vicinity of the resonant frequency indicated by an arrow M3, and in the vicinity of the anti-resonant frequency indicated by an arrow M4. In contrast, in the first example embodiment, it can be understood that the unnecessary waves are reduced or prevented even in any of the vicinity of the frequencies indicated by the arrow M1, the arrow M2, the arrow M3, and the arrow M4. The reason is as follows.

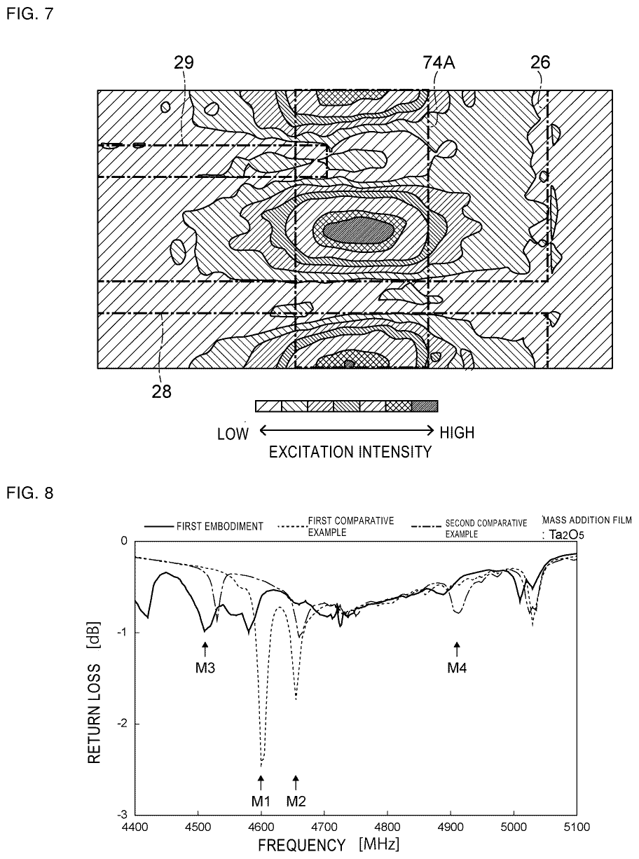

FIG. 7 is a diagram showing excitation intensity of the unnecessary waves in the first comparative example.

In the first comparative example, the excitation intensity of the unnecessary waves is particularly high in a region in which the strip-shaped mass addition film is provided in the portion between the electrode fingers. On the other hand, the excitation intensity of the unnecessary waves is low in a region in which the strip-shaped mass addition film is laminated with the electrode finger. On the other hand, in the second comparative example, the plurality of granular mass addition films are provided not to be located in a portion between the adjacent electrode fingers. Therefore, in the second comparative example, the unnecessary waves in the vicinity of the frequencies indicated by the arrow M1 and the arrow M2 in FIG. 6 are reduced or prevented, compared to the first comparative example. On the other hand, in the first comparative example, the unnecessary waves in the vicinity of the frequencies indicated by the arrow M3 and the arrow M4 are reduced or prevented, compared to the second comparative example.

In the first example embodiment, the strip-shaped mass addition film is provided in the gap region. In this manner, the unnecessary waves can be reduced or prevented in the vicinity of the frequencies indicated by the arrow M3 and the arrow M4 in FIG. 6. In addition, the plurality of granular mass addition films are provided in the edge region, instead of the strip-shaped mass addition film. The plurality of granular mass addition films are provided not to be located in a portion of the adjacent electrode fingers. In this manner, the unnecessary waves can be reduced or prevented in the vicinity of the frequencies indicated by the arrow M1 and the arrow M2.

Furthermore, when Ta₂O₅ is used as the material of the strip-shaped mass addition film and the granular mass addition film, the same comparison as described above is performed. In the first example embodiment related to the comparison, the thickness of the strip-shaped mass addition film and the granular mass addition film is set to about 15 nm, for example.

FIG. 8 is a diagram showing a return loss in the first example embodiment, the first comparative example, and the second comparative example when the material of the strip-shaped mass addition film and the granular mass addition film is Ta₂O₅.

As shown in FIG. 8, it can be understood that even when the strip-shaped mass addition film and the granular mass addition film are formed of Ta₂O₅, the unnecessary waves are reduced or prevented in the first example embodiment, compared to the first comparative example and the second comparative example. As described above, in the first example embodiment, even when the mass addition film is provided in the edge region and the gap region, the unnecessary waves can be reduced or prevented in the vicinity of the resonant frequency or in the vicinity of the anti-resonant frequency. In addition, a transverse mode can also be suppressed.

The materials of the strip-shaped mass addition film and the granular mass addition film are not limited to SiO₂ and Ta₂O₅. For example, the materials of the strip-shaped mass addition film and the granular mass addition film may be silicon oxide, tantalum oxide, niobium oxide, tungsten oxide, or hafnium oxide.

Incidentally, in the first example embodiment, in a portion where the strip-shaped mass addition film and the electrode finger are laminated, the piezoelectric layer 14, the electrode finger, and the strip-shaped mass addition film are laminated in this order. However, in this portion, the piezoelectric layer 14, the strip-shaped mass addition film, and the electrode finger may be laminated in this order.

In the first example embodiment, in a portion where the granular mass addition film and the electrode finger are laminated, the piezoelectric layer 14, the electrode finger, and the granular mass addition film are laminated in this order. However, in this portion, the piezoelectric layer 14, the granular mass addition film, and the electrode finger may be laminated in this order.

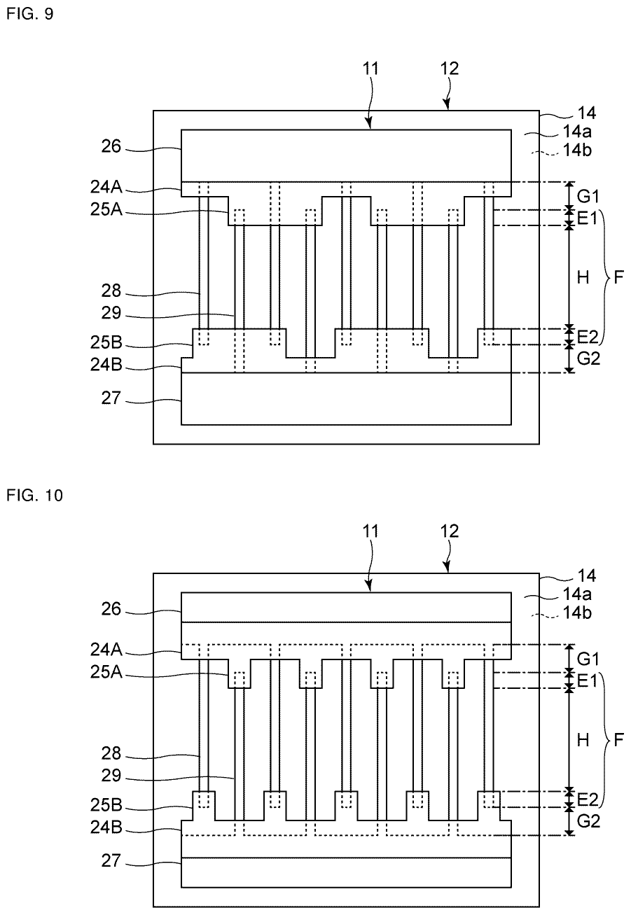

The granular mass addition film may overlap one or more electrode fingers in plan view. For example, in the first modification example of the first example embodiment shown in FIG. 9, the first granular mass addition film 25A overlaps a pair of adjacent first and second electrode fingers 28 and 29 in plan view. When the pair of adjacent first and second electrode fingers 28 and 29 are defined as an electrode finger pair, a portion in a region between two adjacent electrode finger pairs does not overlap the first granular mass addition film 25A in plan view.

The second granular mass addition film 25B overlaps a pair of adjacent first and second electrode fingers 28 and 29 in plan view. A portion in a region between two adjacent electrode finger pairs does not overlap the second granular mass addition film 25B in plan view. As described above, the first granular mass addition film 25A and the second granular mass addition film 25B are provided not to overlap at least a portion in at least a region between the adjacent electrode fingers in plan view.

In the present modification example as well, as in the first example embodiment, both the strip-shaped mass addition film and the granular mass addition film are provided. Therefore, the unnecessary waves can be reduced or prevented in the vicinity of the resonant frequency or in the vicinity of the anti-resonant frequency.

However, it is preferable that the granular mass addition film overlaps only one electrode finger in plan view. In this case, when viewed in plan, the granular mass addition film is not located in at least a portion of any region between the electrode fingers in the edge region. In this manner, the unnecessary waves can be more reliably reduced or prevented.

In the first example embodiment, the strip-shaped mass addition film is provided only in the gap region. However, the present invention is not limited thereto. For example, in the second modification example of the first example embodiment shown in FIG. 10, the first strip-shaped mass addition film 24A extends from the first gap region G1 to a portion overlapping the first busbar 26 in plan view. The second strip-shaped mass addition film 24B also extends from the second gap region G2 to a portion overlapping the second busbar 27 in plan view. However, the strip-shaped mass addition film provided in at least one of the pair of gap regions may extend from the gap region to a portion overlapping the busbar adjacent to the gap region in plan view.

In the present modification example as well, as in the first example embodiment, both the strip-shaped mass addition film and the granular mass addition film are provided. Therefore, the unnecessary waves can be reduced or prevented in the vicinity of the resonant frequency or in the vicinity of the anti-resonant frequency.

In the present modification example, in a portion where the strip-shaped mass addition film and the busbar are laminated, the piezoelectric layer 14, the busbar, and the strip-shaped mass addition film are laminated in this order. In addition, in a portion where the strip-shaped mass addition film and the busbar are laminated, the piezoelectric layer 14, the strip-shaped mass addition film, and the busbar may be laminated in this order.

Returning to FIG. 1, when the dimension of the strip-shaped mass addition film in the electrode finger extending direction is defined as a width of the strip-shaped mass addition film, in the first example embodiment, the width of the first strip-shaped mass addition film 24A is constant. Similarly, the width of the second strip-shaped mass addition film 24B is constant. However, the present invention is not limited thereto.

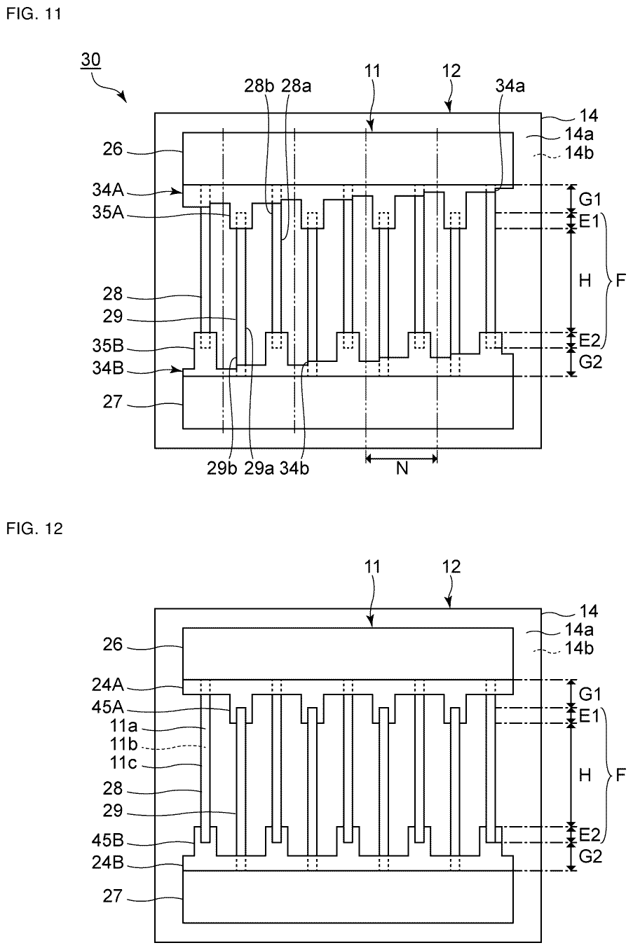

FIG. 11 is a schematic plan view of an acoustic wave device according to a second example embodiment.

The present example embodiment is different from the first example embodiment in that the width of the strip-shaped mass addition film is not constant and the dimension of the granular mass addition film in the electrode finger extending direction is not constant. An acoustic wave device 30 according to the present example embodiment has the same configuration as the configuration of the acoustic wave device 10 according to the first example embodiment except for the above-described point.

The IDT electrode 11 includes a plurality of pairs of first and second electrode fingers 28 and 29. When a region including only the pair of first electrode fingers 28 and second electrode fingers 29 is defined as an electrode finger pair region N, a plurality of the electrode finger pair regions N are provided in the acoustic wave device 30. A boundary between the adjacent electrode finger pair regions N is set as the center in the electrode finger orthogonal direction between the first electrode finger 28 of one electrode finger pair region N and the second electrode finger 29 of the other electrode finger pair region N.

The first strip-shaped mass addition film 34A includes a plurality of stepped portions 34a. In the present example embodiment, the stepped portion 34a extends in the electrode finger extending direction. The first strip-shaped mass addition film 34A has a configuration in which portions having mutually different widths are connected to each other. In the first strip-shaped mass addition film 34A, the stepped portion 34a is a boundary between the portions having mutually different widths. In each portion where the stepped portion 34a is the boundary in the first strip-shaped mass addition film 34A, the width is constant.

Here, each of the plurality of first electrode fingers 28 includes a first end edge portion 28a and a second end edge portion 28b. Specifically, the first end edge portion 28a and the second end edge portion 28b are end edge portions of the first electrode finger 28 in plan view. The first end edge portion 28a and the second end edge portion 28b of each of the first electrode fingers 28 face each other in the electrode finger orthogonal direction. Similarly, each of the plurality of second electrode fingers 29 includes a first end edge portion 29a and a second end edge portion 29b.

Each of the stepped portions 34a of the first strip-shaped mass addition film 34A is located in a portion overlapping the first end edge portion 28a of the first electrode finger 28 in plan view. Therefore, the width of the first strip-shaped mass addition film 34A is constant in a region between the first end edge portions 28a of the adjacent first electrode fingers 28 and the overlapping portion in plan view.

In the following description, when an area of the strip-shaped mass addition film is described, the area refers to an area of the strip-shaped mass addition film in plan view, unless otherwise specified. When an area of the granular mass addition film is described, the area refers to an area of the granular mass addition film in plan view, unless otherwise specified.

As shown in FIG. 11, the stepped portion 34a of the first strip-shaped mass addition film 34A is located in each of the electrode finger pair region N. From one side toward the other side in the electrode finger orthogonal direction, the width of the first strip-shaped mass addition film 34A is widened in a stepwise manner while each of the stepped portions 34a is set as the boundary. Therefore, the areas of the first strip-shaped mass addition films 34A are different from each other in all of the electrode finger pair regions N.

The first strip-shaped mass addition film 34A and the plurality of first granular mass addition films 35A are integrally formed of the same material. The first strip-shaped mass addition film 34A extends to an end edge portion of the first gap region G1 on the first busbar 26 side in the electrode finger extending direction. Therefore, as the width of the first strip-shaped mass addition film 34A is narrower, the dimension of the first granular mass addition film 35A in the electrode finger extending direction is larger.

In addition, in one electrode finger pair region N, the dimension of the first strip-shaped mass addition film 34A in the electrode finger orthogonal direction is larger than the dimension of the first granular mass addition film 35A in the electrode finger orthogonal direction. Therefore, in one electrode finger pair region N, as the width of the first strip-shaped mass addition film 34A is wider, a total area of the first strip-shaped mass addition film 34A and the first granular mass addition film 35A is larger. Therefore, when a total area of the first strip-shaped mass addition film 34A and the first granular mass addition film 35A in one electrode finger pair region N is defined as a first addition film total area, the first addition film total areas are different from each other in all of the electrode finger pair regions N.

Similarly, the second strip-shaped mass addition film 34B includes a plurality of stepped portions 34b. Each of the stepped portions 34b is located in a portion overlapping the second end edge portion 29b of the second electrode finger 29 in plan view. Therefore, the width of the second strip-shaped mass addition film 34B is constant in a region between the second end edge portions 29b of the adjacent second electrode fingers 29 and the overlapping portion in plan view.

The stepped portion 34b of the second strip-shaped mass addition film 34B is located in each of the electrode finger pair region N. From one side toward the other side in the electrode finger orthogonal direction, the width of the second strip-shaped mass addition film 34B is widened in a stepwise manner while each of the stepped portions 34b is set as the boundary. Therefore, the areas of the second strip-shaped mass addition films 34B are different from each other in all of the electrode finger pair regions N.

The second strip-shaped mass addition film 34B and the plurality of second granular mass addition films 35B are integrally formed of the same material. The second strip-shaped mass addition film 34B extends to an end edge portion of the second gap region G2 on the second busbar 27 side in the electrode finger extending direction. Therefore, as the width of the second strip-shaped mass addition film 34B is narrower, the dimension of the second granular mass addition film 35B in the electrode finger extending direction is larger.

In one electrode finger pair region N, the dimension of the second strip-shaped mass addition film 34B in the electrode finger orthogonal direction is larger than the dimension of the second granular mass addition film 35B in the electrode finger orthogonal direction. Therefore, in one electrode finger pair region N, as the width of the second strip-shaped mass addition film 34B is wider, the total area of the second strip-shaped mass addition film 34B and the second granular mass addition film 35B is larger. Therefore, when the total area of the second strip-shaped mass addition film 34B and the second granular mass addition film 35B in one electrode finger pair region N is defined as a second addition film total area, the second addition film total areas are different from each other in all of the electrode finger pair regions N.

The acoustic wave device 30 is an acoustic wave resonator using the bulk wave in the thickness shear mode. In the acoustic wave device 30, a portion where the pair of first electrode fingers 28 and second electrode fingers 29 are provided in the piezoelectric layer 14 functions as one resonator. Therefore, a configuration of the acoustic wave device 30 corresponds to a configuration in which one resonator is provided for each electrode finger pair region N. The configuration of the acoustic wave device 30 corresponds to a configuration in which a plurality of the resonators are connected in parallel.

In the present example embodiment, the first addition film total area and the second addition film total area are different from each other in the electrode finger pair regions N. Therefore, the frequencies of the generated unnecessary waves are different for each electrode finger pair region. In this way, the frequency of the unnecessary waves can be dispersed. Therefore, the unnecessary waves can be effectively reduced or prevented in the vicinity of the resonant frequency or in the vicinity of the anti-resonant frequency.

Incidentally, in a case of an acoustic wave device using a surface acoustic wave, the surface acoustic wave is excited in a region including all of the plurality of electrode fingers. In contrast, the configuration of the acoustic wave device 30 corresponds to a configuration in which the resonators in each of the electrode finger pair regions are connected in parallel as described above. Therefore, even when the first addition film total area and the second addition film total area are not uniform, a waveform in frequency characteristics of the acoustic wave device 30 is less likely to collapse. That is, the unnecessary waves can be reduced or prevented without deteriorating electrical characteristics.

An example embodiment in which the width of the strip-shaped mass addition film is changed is not limited to the above-described configuration. For example, a position of the stepped portion of the strip-shaped mass addition film does not need to overlap the first end edge portion or the second end edge portion of the electrode finger in plan view. The stepped portion may extend in a direction intersecting the electrode finger extending direction.

The first addition film total area in at least one electrode finger pair region N may be different from the total area of the first strip-shaped mass addition film 24A and the first granular mass addition film 35A in the other electrode finger pair region N. Alternatively, the second addition film total area in at least one electrode finger pair region N may be different from the second addition film total area in the other electrode finger pair region N. In these cases, as in the second example embodiment, the unnecessary waves can be effectively reduced or prevented in the vicinity of the resonant frequency or in the vicinity of the anti-resonant frequency.

In the first example embodiment and the second example embodiment, the granular mass addition film is laminated with the tip portion of the electrode finger. In addition, in a portion where the granular mass addition film and the electrode finger are laminated, the piezoelectric layer 14, the electrode finger, and the granular mass addition film are laminated in this order. However, the present invention is not limited thereto. In the following, an example in which the configuration of the granular mass addition film is different from the configurations of the first example embodiment and the second example embodiment will be described with reference to third to fifth example embodiments.

The acoustic wave device according to the third to fifth example embodiments has the same configuration as the configuration of the acoustic wave device 10 according to the first example embodiment, except for the granular mass addition film. That is, in the third to fifth example embodiments as well, both the strip-shaped mass addition film and the granular mass addition film are provided. In this manner, in the third to fifth example embodiments as well, as in the first example embodiment, even when the mass addition film is provided in the edge region and the gap region, the unnecessary waves can be reduced or prevented in the vicinity of the resonant frequency or in the vicinity of the anti-resonant frequency.

FIG. 12 is a schematic plan view of the acoustic wave device according to the third example embodiment.

In the present example embodiment, a first granular mass addition film 45A surrounds the tip portion of the second electrode finger 29 in three directions in plan view. The first granular mass addition film 45A is in contact with the second electrode finger 29. However, the first granular mass addition film 45A does not overlap the second electrode finger 29 in plan view. A shape of the first granular mass addition film 45A in plan view is a U-shape.

More specifically, the plurality of electrode fingers include a first surface 11a, a second surface 11b, and a side surface 11c. The first surface 11a and the second surface 11b face each other in a thickness direction. Out of the first surface 11a and the second surface 11b, the second surface 11b is a surface on the piezoelectric layer 14 side. The side surface 11c is connected to the first surface 11a and the second surface 11b. The first granular mass addition film 45A is in contact with the side surface 11c of the second electrode finger 29.

When viewed in plan, a portion located in the first gap region G1 of the first granular mass addition film 45A is located on an extension line of the second electrode finger 29.

Similarly, the second granular mass addition film 45B surrounds the tip portion of the first electrode finger 28 in three directions in plan view. The second granular mass addition film 45B is in contact with the side surface 11c of the first electrode finger 28. However, the second granular mass addition film 45B does not overlap the first electrode finger 28 in plan view. A shape of the second granular mass addition film 45B in plan view is a U-shape. When viewed in plan, a portion located in the second gap region G2 in the second granular mass addition film 45B is located on an extension line of the first electrode finger 28.

The plurality of granular mass addition films may include at least one granular mass addition film that surrounds the tip portion of the electrode finger in three directions in plan view.

In the present example embodiment, the granular mass addition film does not overlap the tip portion of the electrode finger in plan view. In this manner, mass addition in the tip portion of the electrode finger decreases. In this manner, electric power handling capability of the acoustic wave device can be improved.

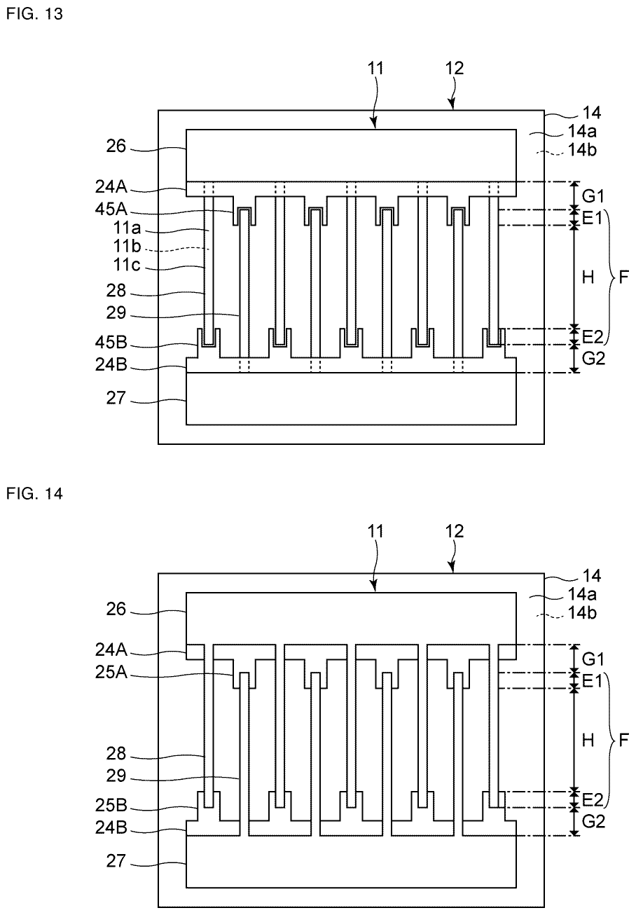

FIG. 13 is a schematic plan view of the acoustic wave device according to the fourth example embodiment.

In the present example embodiment, the first granular mass addition film 45A surrounds the tip portion of the second electrode finger 29 in three directions in plan view. However, the first granular mass addition film 45A is not in contact with the side surface 11c of the second electrode finger 29. In addition, the first granular mass addition film 45A does not overlap the second electrode finger 29 in plan view. When viewed in plan, a portion located in the first gap region G1 of the first granular mass addition film 45A is located on an extension line of the second electrode finger 29.

Similarly, the second granular mass addition film 45B surrounds the tip portion of the first electrode finger 28 in three directions in plan view. The second granular mass addition film 45B is not in contact with the side surface 11c of the first electrode finger 28. In addition, the second granular mass addition film 45B does not overlap the first electrode finger 28 in plan view. When viewed in plan, a portion located in the second gap region G2 in the second granular mass addition film 45B is located on an extension line of the first electrode finger 28.

As in the third example embodiment, in the present example embodiment as well, electric power handling capability of the acoustic wave device can be improved.

FIG. 14 is a schematic plan view of the acoustic wave device according to the fifth example embodiment.

In the present example embodiment, the first granular mass addition film 25A overlaps the tip portion of the second electrode finger 29 in plan view. Specifically, in a portion where the first granular mass addition film 25A and the second electrode finger 29 are laminated, the piezoelectric layer 14, the first granular mass addition film 25A, and the second electrode finger 29 are laminated in this order.

Similarly, the second granular mass addition film 25B overlaps the tip portion of the first electrode finger 28 in plan view. Specifically, in a portion where the second granular mass addition film 25B and the first electrode finger 28 are laminated, the piezoelectric layer 14, the second granular mass addition film 25B, and the first electrode finger 28 are laminated in this order.

In the present example embodiment, the granular mass addition film is provided between the piezoelectric layer 14 and the tip portion of the electrode finger. In this manner, an electric field applied to the electrode finger is reduced or prevented. In this manner, electric power handling capability of the acoustic wave device can be improved.

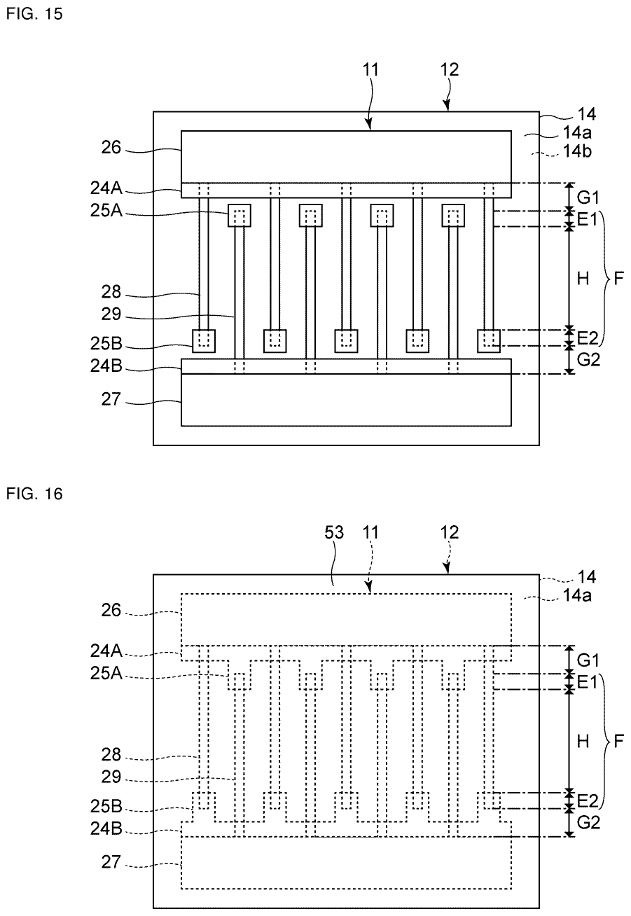

FIG. 15 is a schematic plan view of the acoustic wave device according to the sixth example embodiment.

The present example embodiment is different from the first example embodiment in that the strip-shaped mass addition film and the plurality of granular mass addition films which are located in the same gap region are individually provided. The strip-shaped mass addition film and the plurality of granular mass addition films are not in contact with each other. The acoustic wave device of the present example embodiment has the same configurations as the configuration of the acoustic wave device 10 of the first example embodiment, except for the above-described points.

The first strip-shaped mass addition film 24A and each first granular mass addition film 25A face each other with a gap therebetween. Each first granular mass addition film 25A is extending over the first gap region G1 and the first edge region E1. Therefore, the gap between the first strip-shaped mass addition film 24A and each first granular mass addition film 25A is located in the first gap region G1.

The second strip-shaped mass addition film 24B and the second granular mass addition films 25B face each other with a gap therebetween. Each second granular mass addition film 25B is extending over the second gap region G2 and the second edge region E2. Therefore, the gap between the second strip-shaped mass addition film 24B and each second granular mass addition film 25B is located in the second gap region G2. In the present example embodiment, the material of the strip-shaped mass addition film and the material of the granular mass addition film are the same as each other.

In the present example embodiment as well, as in the first example embodiment, even when the mass addition film is provided in the edge region and the gap region, the unnecessary waves can be reduced or prevented in the vicinity of the resonant frequency or in the vicinity of the anti-resonant frequency.

The configuration in which the strip-shaped mass addition film and the plurality of granular mass addition films which are located in the same gap region are individually provided can also be applied to other example embodiments of the present invention.

FIG. 16 is a schematic plan view of the acoustic wave device according to the seventh example embodiment.

The present example embodiment is different from the first example embodiment in that a dielectric film 53 is provided on the piezoelectric layer 14. The acoustic wave device of the present example embodiment has the same configurations as the configuration of the acoustic wave device 10 of the first example embodiment, except for the above-described points.

The dielectric film 53 is provided on the first main surface 14a of the piezoelectric layer 14 to cover the IDT electrode 11, the first strip-shaped mass addition film 24A, the plurality of first granular mass addition films 25A, the second strip-shaped mass addition film 24B, and the plurality of second granular mass addition films 25B.

In a portion where the strip-shaped mass addition film and the dielectric film 53 are laminated, the piezoelectric layer 14, the strip-shaped mass addition film, and the dielectric film 53 are laminated in this order. In a portion where the granular mass addition film and the dielectric film 53 are laminated, the piezoelectric layer 14, the granular mass addition film, and the dielectric film 53 are laminated in this order.

In the present example embodiment, both the strip-shaped mass addition film and the granular mass addition film are provided. In this manner, as in the first example embodiment, even when the mass addition film is provided in the edge region and the gap region, the unnecessary waves can be reduced or prevented in the vicinity of the resonant frequency or in the vicinity of the anti-resonant frequency.

In addition, the IDT electrode 11 is protected by the dielectric film 53. In this manner, the IDT electrode 11 is less likely to be damaged. Furthermore, the frequency of the acoustic wave device can be easily adjusted by adjusting the thickness of the dielectric film 53.

As the dielectric film 53, for example, silicon oxide, silicon nitride, silicon oxynitride, or the like can be used. The material of the dielectric film 53 is not limited to the above-described material.

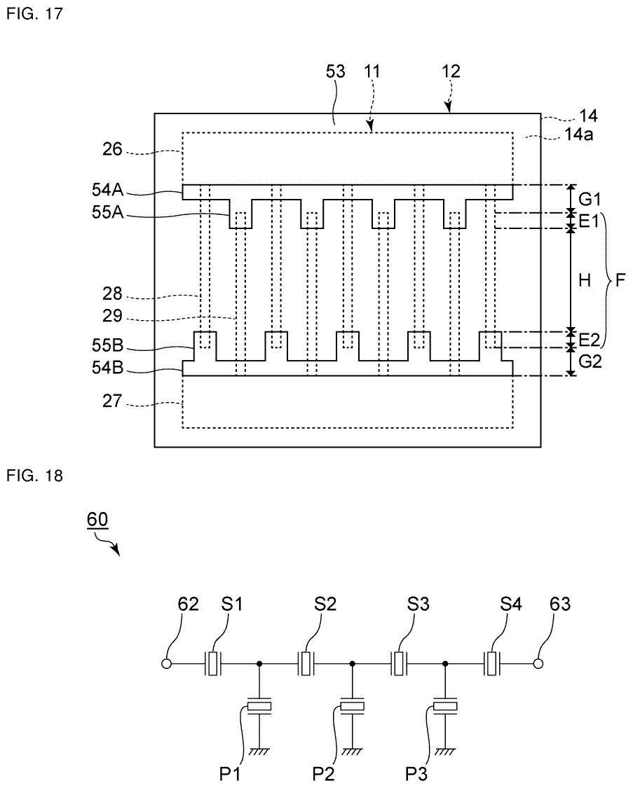

The order of laminating the strip-shaped mass addition film, the granular mass addition film, and the dielectric film 53 is not limited to the above-described order. For example, in a modification example of the seventh example embodiment shown in FIG. 17, the dielectric film 53 is provided on the first main surface 14a of the piezoelectric layer 14 to cover the IDT electrode 11. The first strip-shaped mass addition film 54A, a plurality of first granular mass addition films 55A, a second strip-shaped mass addition film 54B, and a plurality of second granular mass addition films 55B are provided on the dielectric film 53.

The first strip-shaped mass addition film 54A is provided in the first gap region G1. The first strip-shaped mass addition film 54A is continuously provided to overlap the plurality of first electrode fingers 28, the plurality of second electrode fingers 29, and the region between the electrode fingers in plan view. Each of the plurality of first granular mass addition films 55A is extending over the first edge region E1 and the first gap region G1.

The second strip-shaped mass addition film 54B is provided in the second gap region G2. The second strip-shaped mass addition film 54B is continuously provided to overlap the plurality of first electrode fingers 28, the plurality of second electrode fingers 29, and the region between the electrode fingers in plan view. Each of the plurality of second granular mass addition films 55B is extending over the second edge region E2 and the second gap region G2.

In a portion where the strip-shaped mass addition film and the dielectric film 53 are laminated, the piezoelectric layer 14, the dielectric film 53, and the strip-shaped mass addition film are laminated in this order. In a portion where the granular mass addition film and the dielectric film 53 are laminated, the piezoelectric layer 14, the dielectric film 53, and the granular mass addition film are laminated in this order. In this case as well, as in the seventh example embodiment, the unnecessary waves can be reduced or prevented in the vicinity of the resonant frequency or in the vicinity of the anti-resonant frequency.

In the present modification example, the strip-shaped mass addition film is not in contact with the plurality of electrode fingers connected to mutually different potentials. In this case, the strip-shaped mass addition film may be formed of metal. The plurality of granular mass addition films are not electrically connected to the plurality of electrode fingers connected to mutually different potentials. In this case, the plurality of granular mass addition films may be formed of metal. However, in the present modification example as well, the strip-shaped mass addition film and the plurality of granular mass addition films may include a dielectric.

An acoustic wave device according to an example embodiment of the present invention can be used for a filter device, for example. This example will be described below.

FIG. 18 is a circuit diagram of a filter device according to an eighth example embodiment of the present invention.

A filter device 60 is a ladder filter. The filter device 60 includes a first signal terminal 62, a second signal terminal 63, a plurality of series arm resonators, and a plurality of parallel arm resonators. In the present example embodiment, all of the series arm resonators and all of the parallel arm resonators are acoustic wave resonators. All of the acoustic wave resonators are the acoustic wave devices according to the present invention. However, at least one acoustic wave resonator of the series arm resonator and the parallel arm resonator in the filter device 60 may be an acoustic wave device according to another example embodiment of the present invention, which has any configuration of the first to seventh example embodiments, for example.

For example, the first signal terminal 62 and the second signal terminal 63 may be configured as an electrode pad, or may be configured as a wire. In the present example embodiment, the second signal terminal 63 is an antenna terminal. The antenna terminal is connected to an antenna.

Specifically, the plurality of series arm resonators of the filter device 60 are a series arm resonator S1, a series arm resonator S2, a series arm resonator S3, and a series arm resonator S4. Specifically, the plurality of parallel arm resonators are a parallel arm resonator P1, a parallel arm resonator P2, and a parallel arm resonator P3.

The series arm resonators S1, S2, S3, and S4 are connected in series to each other between the first signal terminal 62 and the second signal terminal 63. The parallel arm resonator P1 is connected between a connection point of the series arm resonator S1 and the series arm resonator S2, and a ground potential. The parallel arm resonator P2 is connected between a connection point of the series arm resonator S2 and the series arm resonator S3, and the ground potential. The parallel arm resonator P3 is connected between a connection point of the series arm resonator S3 and the series arm resonator S4, and the ground potential.

However, the circuit configuration of the filter device 60 is not limited to the above-described configuration. When the filter device 60 according to an example embodiment of the present invention is a ladder filter, the filter device 60 may include at least one series arm resonator and at least one parallel arm resonator.

Alternatively, for example, the filter device 60 may include a longitudinally coupled resonator-type acoustic wave filter. In this case, for example, the filter device 60 may include the series arm resonator or the parallel arm resonator connected to the longitudinally coupled resonator-type acoustic wave filter. The series arm resonator or the parallel arm resonator may be an acoustic wave device according to another example embodiment of the present invention.

The anti-resonant frequency of the parallel arm resonator forming a pass band of the filter device 60 is located inside the pass band of the filter device 60. Therefore, influence of the unnecessary waves generated in the vicinity of the anti-resonant frequency in the parallel arm resonator is great on electrical characteristics inside the pass band in the filter device 60. The resonant frequency of the series arm resonator forming the pass band of the filter device 60 is located inside the pass band of the filter device 60. Therefore, the influence of the unnecessary waves generated in the vicinity of the resonant frequency in the series arm resonator is also great on the electrical characteristics inside the pass band in the filter device 60.

In the present example embodiment, each of the parallel arm resonators and each of the series arm resonators are an acoustic wave device according to another example embodiment of the present invention. Therefore, in each acoustic wave resonator of the filter device 60, even when the mass addition film is provided in the edge region and the gap region, the unnecessary waves can be reduced or prevented in the vicinity of the resonant frequency or in the vicinity of the anti-resonant frequency.

For each of the parallel arm resonators of the filter device 60, for example, the acoustic wave device which can reduce or prevent the unnecessary waves in the vicinity of an anti-resonant frequency may be used. For example, the acoustic wave device which can reduce or prevent the unnecessary waves in the vicinity of the resonant frequency may be used for each of the series arm resonators. In this manner, it is possible to reduce or prevent the influence of the unnecessary waves on the electrical characteristics inside the pass band of the filter device 60. In addition, when the acoustic wave device of the first example embodiment or the like is used as the series arm resonator or the parallel arm resonator, it is possible to reduce or prevent deterioration in the loss in the acoustic wave resonator. Therefore, deterioration in the filter characteristics of the filter device 60 can be reduced or prevented.

Hereinafter, a ninth example embodiment which is different from the eighth example embodiment in the configuration of each acoustic wave resonator will be described. In the ninth example embodiment, the circuit configuration is the same as that of the eighth example embodiment. Therefore, in the description of the ninth example embodiment, reference numerals and drawings which are used in the description of the eighth example embodiment will be used.

The plurality of acoustic wave resonators of the filter device according to the ninth example embodiment include first to fifth acoustic wave resonators. The first acoustic wave resonator is an acoustic wave device according to another example embodiment of the present invention. For example, the first acoustic wave resonator may have any of the configurations of the first to seventh example embodiments. The second to fifth acoustic wave resonators are not an acoustic wave device according to another example embodiment of the present invention.

The series arm resonator S1 shown with reference to FIG. 18 is the third acoustic wave resonator. The series arm resonator S2 is the first acoustic wave resonator. The series arm resonator S3 is the fifth acoustic wave resonator. The series arm resonator S4 is the fourth acoustic wave resonator. The parallel arm resonator P1 is the third acoustic wave resonator. The parallel arm resonator P2 is the second acoustic wave resonator. The parallel arm resonator P3 is the fourth acoustic wave resonator. The disposition of the first to fifth acoustic wave resonators on the circuit is not limited to the above-described configuration.

In the present example embodiment, all of the acoustic wave resonators share the piezoelectric substrate. Hereinafter, specific configurations of the second to fifth acoustic wave resonators will be described.

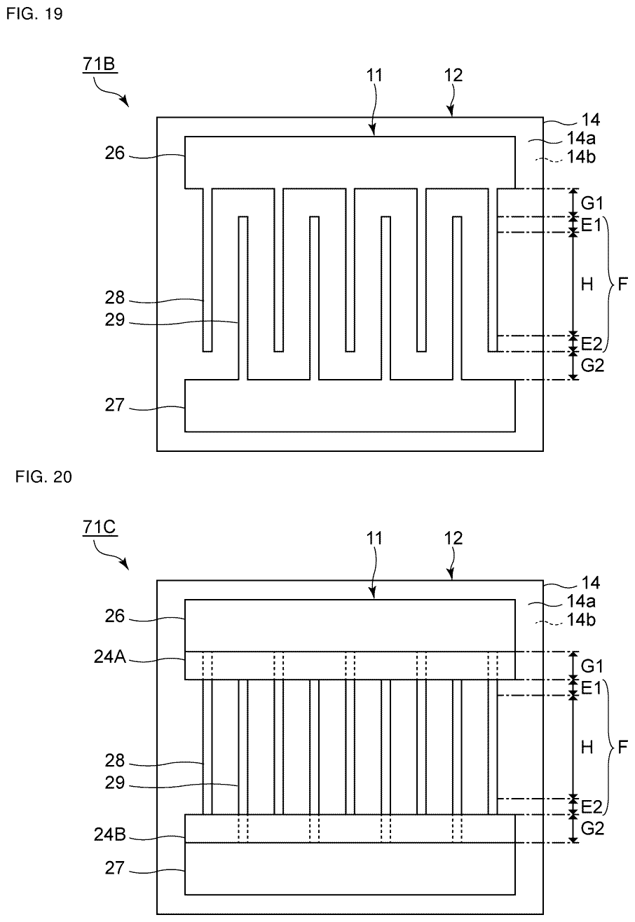

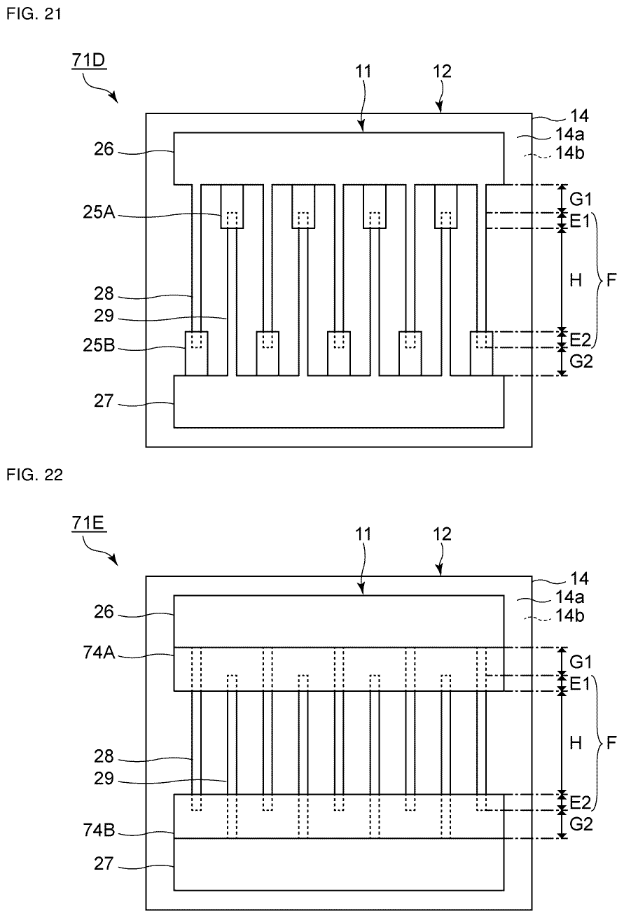

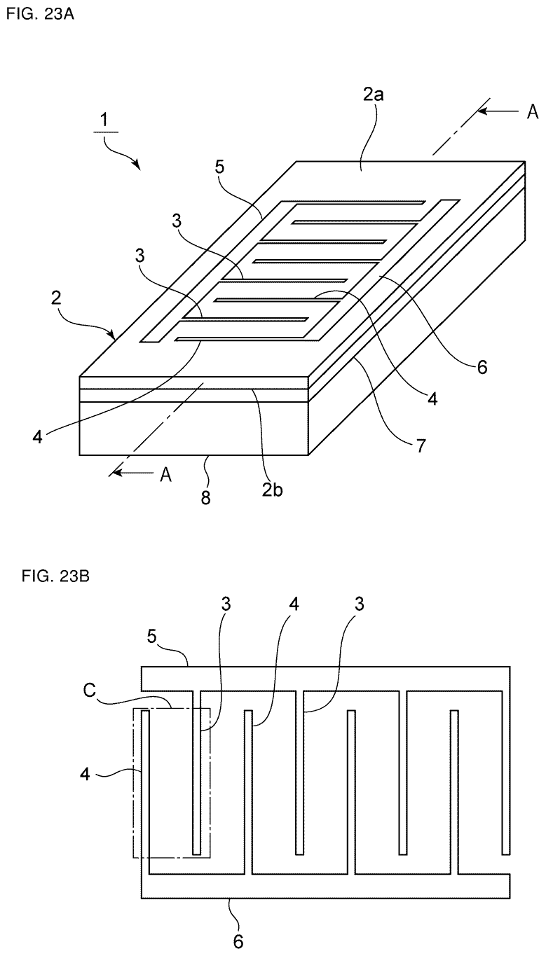

FIG. 19 is a schematic plan view of the second acoustic wave resonator in the ninth example embodiment. FIG. 20 is a schematic plan view of the third acoustic wave resonator in the ninth example embodiment. FIG. 21 is a schematic plan view of the fourth acoustic wave resonator in the ninth example embodiment. FIG. 22 is a schematic plan view of the fifth acoustic wave resonator in the ninth example embodiment.

As shown in FIG. 19, a second acoustic wave resonator 71B includes the piezoelectric substrate 12. The second acoustic wave resonator 71B shares the piezoelectric substrate 12 with the first acoustic wave resonator. Each of a third acoustic wave resonator 71C, a fourth acoustic wave resonator 71D, and a fifth acoustic wave resonator 71E which are shown in FIGS. 20 to 22 also includes the piezoelectric substrate 12. The third acoustic wave resonator 71C, the fourth acoustic wave resonator 71D, and the fifth acoustic wave resonator 71E share the piezoelectric substrate 12 with the first acoustic wave resonator.

The second acoustic wave resonator 71B, the third acoustic wave resonator 71C, the fourth acoustic wave resonator 71D, and the fifth acoustic wave resonator 71E may include the piezoelectric substrate separate and independent from the first acoustic wave resonator. In this case, each piezoelectric substrate may be configured in the same manner as the piezoelectric substrate 12 of the acoustic wave device 10 according to the first example embodiment, for example. For example, as shown with reference to FIG. 2, the piezoelectric substrate 12 may include the support 13 and the piezoelectric layer 14.

As shown in FIG. 19, the second acoustic wave resonator 71B includes the IDT electrode 11. The IDT electrode 11 is provided on the piezoelectric substrate 12. The IDT electrode 11 includes the pair of busbars and the plurality of electrode fingers. The IDT electrode 11 is configured in the same manner as the IDT electrode 11 of the acoustic wave device 10 according to the first example embodiment.

Specifically, the IDT electrode 11 of the second acoustic wave resonator 71B includes the pair of busbars and the plurality of electrode fingers. More specifically, the pair of busbars are the first busbar 26 and the second busbar 27. The first busbar 26 and the second busbar 27 face each other. More specifically, the plurality of electrode fingers are the plurality of first electrode fingers 28 and the plurality of second electrode fingers 29. Each one end of the plurality of first electrode fingers 28 is connected to the first busbar 26. Each one end of the plurality of second electrode fingers 29 is connected to the second busbar 27. The plurality of first electrode fingers 28 and the plurality of second electrode fingers 29 are interdigitated with each other.

Similarly, in each of the third acoustic wave resonator 71C, the fourth acoustic wave resonator 71D, and the fifth acoustic wave resonator 71E which are shown in FIGS. 20 to 22, the IDT electrode 11 is provided on the piezoelectric substrate 12. The IDT electrode 11 of each of the third acoustic wave resonator 71C, the fourth acoustic wave resonator 71D, and the fifth acoustic wave resonator 71E is configured in the same manner as the IDT electrode 11 of the acoustic wave device 10 according to the first example embodiment.

Design parameters of the IDT electrodes 11 of the first acoustic wave resonator, the second acoustic wave resonator 71B, the third acoustic wave resonator 71C, the fourth acoustic wave resonator 71D, and the fifth acoustic wave resonator 71E may be different from each other depending on desired electrical characteristics.

As shown in FIG. 19, the second acoustic wave resonator 71B includes the intersecting region F and the pair of gap regions, as in the acoustic wave device 10 according to the first example embodiment.

Specifically, in the second acoustic wave resonator 71B, when the IDT electrode 11 is viewed in the direction orthogonal to the direction in which the plurality of electrode fingers extend, a region in which adjacent electrode fingers overlap each other is the intersecting region F. The intersecting region F includes a central region H and a pair of edge regions. More specifically, the pair of edge regions are the first edge region E1 and the second edge region E2. The first edge region E1 and the second edge region E2 extend across the central region H in the direction in which the plurality of electrode fingers extend. The first edge region E1 is located on the first busbar 26 side. The second edge region E2 is located on the second busbar 27 side.

In the second acoustic wave resonator 71B, a region located between the intersecting region F and the pair of busbars is the pair of gap regions. Specifically, the pair of gap regions are a first gap region G1 and a second gap region G2. The first gap region G1 is located between the first busbar 26 and the first edge region E1. The second gap region G2 is located between the second busbar 27 and the second edge region E2.

Similarly, each of the third acoustic wave resonator 71C, the fourth acoustic wave resonator 71D, and the fifth acoustic wave resonator 71E which are shown in FIGS. 20 to 22 includes the intersecting region F, the first gap region G1, and the second gap region G2. In addition, each of the intersecting regions F of the third acoustic wave resonator 71C, the fourth acoustic wave resonator 71D, and the fifth acoustic wave resonator 71E which are shown in FIGS. 20 to 22 includes the central region H, the first edge region E1, and the second edge region E2.

As described above, the second acoustic wave resonator 71B, the third acoustic wave resonator 71C, the fourth acoustic wave resonator 71D, and the fifth acoustic wave resonator 71E include the piezoelectric substrate 12 and the IDT electrode 11. Each of the acoustic wave resonators includes the intersecting region F and the pair of gap regions. However, the respective acoustic wave resonators are different from each other in the configuration related to the mass addition film.

As shown in FIG. 19, the second acoustic wave resonator 71B does not include the mass addition film. Therefore, the second acoustic wave resonator 71B does not include the mass addition film corresponding to the strip-shaped mass addition film or the granular mass addition film in the first acoustic wave resonator.

As shown in FIG. 20, the third acoustic wave resonator 71C does not include the mass addition film corresponding to the granular mass addition film of the first acoustic wave resonator. On the other hand, the third acoustic wave resonator 71C includes the strip-shaped mass addition film separate and independent from the first acoustic wave resonator.

In the third acoustic wave resonator 71C, the first strip-shaped mass addition film 24A is provided in the first gap region G1. On the other hand, the second strip-shaped mass addition film 24B is provided in the second gap region G2. The first strip-shaped mass addition film 24A and the second strip-shaped mass addition film 24B are not provided in the intersecting region F. The first strip-shaped mass addition film 24A and the second strip-shaped mass addition film 24B are continuously provided to overlap the plurality of electrode fingers and the region between the electrode fingers in plan view.

In the third acoustic wave resonator 71C, the strip-shaped mass addition film may be provided in at least one gap region of the pair of gap regions, and does not need to be provided in the intersecting region F. The strip-shaped mass addition film may be continuously provided to overlap the plurality of electrode fingers and the region between the electrode fingers in plan view.

As shown in FIG. 21, the fourth acoustic wave resonator 71D does not include the mass addition film corresponding to the strip-shaped mass addition film of the first acoustic wave resonator. On the other hand, the fourth acoustic wave resonator 71D includes the plurality of granular mass addition films separate from the first acoustic wave resonator.

In the fourth acoustic wave resonator 71D, the plurality of first granular mass addition films 25A are extending over the first gap region G1 and the first edge region E1. On the other hand, the plurality of second granular mass addition films 25B are extending over the second gap region G2 and the second edge region E2. Each of the plurality of first granular mass addition films 25A and the plurality of second granular mass addition films 25B overlaps one electrode finger in plan view.

In the fourth acoustic wave resonator 71D, the plurality of granular mass addition films may be extending over at least one gap region of the pair of gap regions and the edge region adjacent to the gap region. Each of the plurality of granular mass addition films may be provided not to overlap at least a portion in at least a region between the adjacent electrode fingers in plan view. The granular mass addition film may overlap one or less electrode finger in plan view, or may overlap one or more electrode fingers.

When the granular mass addition film does not overlap the electrode finger in plan view, it is preferable that a portion provided in the gap region in the granular mass addition film is located on an extension line of the electrode finger in plan view.

As shown in FIG. 22, the fifth acoustic wave resonator 71E does not include the mass addition film corresponding to the granular mass addition film in the first acoustic wave resonator. On the other hand, the fifth acoustic wave resonator includes the strip-shaped mass addition film separate and independent from the first acoustic wave resonator.

In the fifth acoustic wave resonator 71E, the first strip-shaped mass addition film 74A is extending over the first gap region G1 and the first edge region E1. On the other hand, the second strip-shaped mass addition film 74B is extending over the second gap region G2 and the second edge region E2. The first strip-shaped mass addition film 74A and the second strip-shaped mass addition film 74B are continuously provided to overlap the plurality of electrode fingers and the region between the electrode fingers in plan view.

In the fifth acoustic wave resonator 71E, the strip-shaped mass addition film may be extending over at least one gap region of the pair of gap regions and the edge region adjacent to the gap region. The strip-shaped mass addition film may be continuously provided to overlap the plurality of electrode fingers and the region between the electrode fingers in plan view.

The filter device according to the ninth example embodiment includes the acoustic wave device according to the present invention, as the first acoustic wave resonator. Therefore, in the first acoustic wave resonator of the filter device, even when the mass addition film is provided in the edge region and the gap region, the unnecessary waves can be reduced or prevented in the vicinity of the resonant frequency or in the vicinity of the anti-resonant frequency.

In addition, the configurations related to the mass addition film are different from each other in the first acoustic wave resonator, the second acoustic wave resonator 71B, the third acoustic wave resonator 71C, the fourth acoustic wave resonator 71D, and the fifth acoustic wave resonator 71E. In this manner, in the ninth example embodiment, the frequency at which the unnecessary waves are generated can be dispersed. In this manner, the unnecessary waves can be effectively reduced or prevented.

In the present example embodiment, all of the first acoustic wave resonator, the second acoustic wave resonator 71B, the third acoustic wave resonator 71C, the fourth acoustic wave resonator 71D, and the fifth acoustic wave resonator 71E are configured such that the bulk wave in the thickness shear mode can be used. In any of these acoustic wave resonators, it is preferable that d/p is about 0.5 or smaller, for example.

The series arm resonator or the parallel arm resonator of the filter device may include at least one first acoustic wave resonator. The series arm resonator and the parallel arm resonator of the filter device may include at least one second acoustic wave resonator 71B, the third acoustic wave resonator 71C, the fourth acoustic wave resonator 71D, or the fifth acoustic wave resonator 71E. In this case, the frequency at which the unnecessary waves are generated can be dispersed.

Hereinafter, details of the thickness shear mode will be described. The “electrode” in the IDT electrode (to be described later) corresponds to the electrode finger according to the present invention. The support in the following example corresponds to the support substrate according to an example embodiment of the present invention.

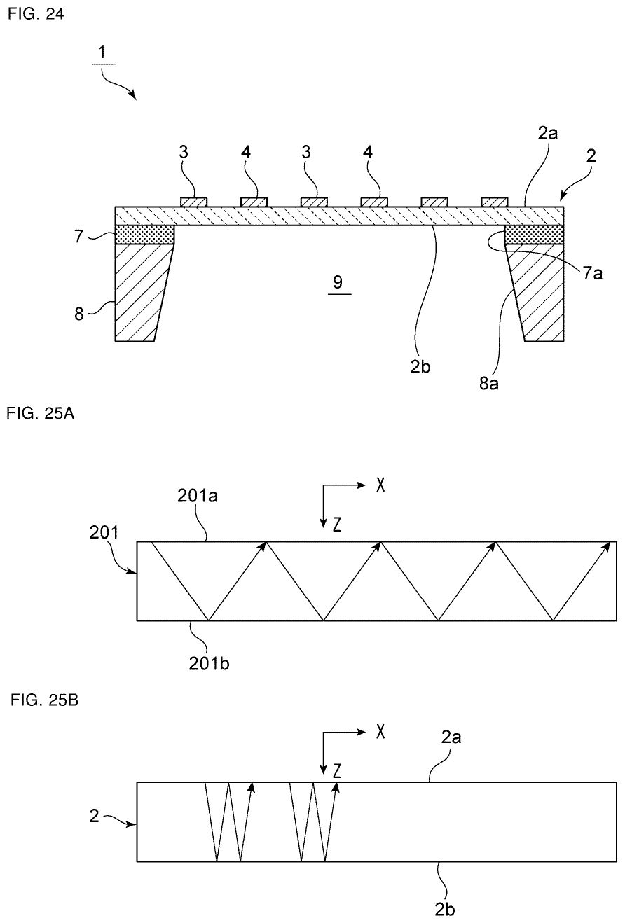

FIG. 23A is a schematic perspective view showing an appearance of the acoustic wave device using the bulk wave in the thickness shear mode, FIG. 23B is a plan view showing an electrode structure on the piezoelectric layer, and FIG. 24 is a cross-sectional view of a portion taken along line A-A in FIG. 23A.

The acoustic wave device 1 includes the piezoelectric layer 2 formed of LiNbO₃. The piezoelectric layer 2 may be formed of LiTaO₃. Cut-angles of LiNbO₃ or LiTaO₃ are Z-cut, but may be a rotated Y-cut or X-cut. The thickness of the piezoelectric layer 2 is not particularly limited, but is preferably about 40 nm or larger and about 1,000 nm or smaller, and more preferably about 50 nm or larger and about 1,000 nm or smaller, for example, in order to effectively excite the thickness shear mode. The piezoelectric layer 2 has first and second main surfaces 2a and 2b facing each other. Electrodes 3 and 4 are provided on the first main surface 2a. Here, the electrode 3 is an example of a “first electrode”, and the electrode 4 is an example of a “second electrode”. In FIGS. 23A and 23B, the plurality of electrodes 3 are a plurality of first electrode fingers connected to a first busbar 5. The plurality of electrodes 4 are a plurality of second electrode fingers connected to a second busbar 6. The plurality of electrodes 3 and the plurality of electrodes 4 are interdigitated with each other. The electrode 3 and the electrode 4 have a rectangular shape, and have a length direction. The electrode 3 and the electrode 4 adjacent thereto face each other in a direction orthogonal to the length direction. Both the length direction of the electrodes 3 and 4 and the direction orthogonal to the length direction of the electrodes 3 and 4 are directions intersecting the thickness direction of the piezoelectric layer 2. Therefore, the electrode 3 and the electrode 4 adjacent thereto may face each other in the direction intersecting the thickness direction of the piezoelectric layer 2. In addition, the length direction of the electrodes 3 and 4 may be replaced with a direction orthogonal to the length direction of the electrodes 3 and 4 shown in FIGS. 23A and 23B. That is, in FIGS. 23A and 23B, the electrodes 3 and 4 may extend in the extending direction of the first busbar 5 and the second busbar 6. In this case, the first busbar 5 and the second busbar 6 extend in the extending direction of the electrodes 3 and 4 in FIGS. 23A and 23B. A plurality of pairs of structures in which the electrode 3 connected to one potential and the electrode 4 connected to the other potential are adjacent to each other are provided in the direction orthogonal to the length direction of the electrodes 3 and 4. Here, a case where the electrodes 3 and 4 are adjacent to each other does not mean a case where the electrodes 3 and 4 are disposed to be in direct contact with each other, but means a case where the electrodes 3 and 4 are disposed with an interval therebetween. In addition, when the electrodes 3 and 4 are adjacent to each other, the electrode connected to a hot electrode or a ground electrode, including the other electrodes 3 and 4, is not disposed between the electrodes 3 and 4. The number of pairs does not need to be integer pairs, but may be 1.5 pairs, 2.5 pairs, or the like. The center-to-center distance, that is, a pitch between the electrodes 3 and 4 is preferably in a range of about 1 μm or larger and about 10 μm or smaller, for example. In addition, the widths of the electrodes 3 and 4, that is, the dimensions of the electrodes 3 and 4 in the facing direction are preferably in a range of about 50 nm or larger and about 1,000 nm or smaller, and more preferably in a range of about 150 nm or larger and about 1,000 nm or smaller, for example. The center-to-center distance between the electrodes 3 and 4 is a distance connecting the center of the dimension (width dimension) of the electrode 3 in the direction orthogonal to the length direction of the electrode 3 and the center of the dimension (width dimension) of the electrode 4 in the direction orthogonal to the length direction of the electrode 4.

In the acoustic wave device 1, since the Z-cut piezoelectric layer is used, the direction orthogonal to the length direction of the electrodes 3 and 4 is a direction orthogonal to a polarization direction of the piezoelectric layer 2. When piezoelectric bodies with different cut-angles are used as the piezoelectric layer 2, this case is an exception. Here, description of “orthogonal” is not limited to being strictly orthogonal, but may be substantially orthogonal (angle formed between the direction orthogonal to the length direction of the electrodes 3 and 4 and the polarization direction falls within a range of 90°+10°, for example).

A support 8 is laminated on the second main surface 2b side of the piezoelectric layer 2 with an insulating layer 7 interposed therebetween. The insulating layer 7 and the support 8 have a frame shape, and include through holes 7a and 8a as shown in FIG. 24. In this manner, a cavity portion 9 is formed. The cavity portion 9 enables free vibration of the excitation region C of the piezoelectric layer 2. Therefore, the support 8 is laminated on the second main surface 2b with the insulating layer 7 interposed therebetween at a position not overlapping the portion where at least the pair of electrodes 3 and 4 are provided. The insulating layer 7 does not have to be provided. Therefore, the support 8 can be directly or indirectly laminated on the second main surface 2b of the piezoelectric layer 2.

The insulating layer 7 is formed of silicon oxide. In addition to silicon oxide, an appropriate insulating material such as silicon oxynitride or alumina can be used. The support 8 is formed of Si. A plane orientation of a surface of Si on the piezoelectric layer 2 side may be (100), (110), or (111). It is desirable that Si forming the support 8 is high resistance having resistivity of about 4 kΩcm or higher, for example. The support 8 can also be formed of an appropriate insulating material or semiconductor material.

Examples of the material of the support 8 include piezoelectric bodies such as aluminum oxide, lithium tantalate, lithium niobate, or quartz crystal, various ceramics such as alumina, magnesia, sapphire, silicon nitride, aluminum nitride, silicon carbide, zirconia, cordierite, mullite, steatite, or forsterite, dielectrics such as diamond or glass, or semiconductors such as gallium nitride.

The plurality of electrodes 3 and 4 and the first and second busbars 5 and 6 are formed of appropriate metal or alloys such as Al or AlCu alloys. In the acoustic wave device 1, the electrodes 3 and 4 and the first and second busbars 5 and 6 have a structure in which Al films are laminated on a Ti film. An adhesion layer other than the Ti film may be used.

During driving, an AC voltage is applied between the plurality of electrodes 3 and the plurality of electrodes 4. More specifically, the AC voltage is applied between the first busbar 5 and the second busbar 6. In this manner, it is possible to obtain the resonance characteristics using the bulk wave in the thickness shear mode excited in the piezoelectric layer 2. In the acoustic wave device 1, when the thickness of the piezoelectric layer 2 is defined as d and the center-to-center distance between any adjacent electrodes 3 and 4 in the plurality of pairs of electrodes 3 and 4 is defined as p, d/p is about 0.5 or smaller, for example. In this manner, the bulk wave in the thickness shear mode is effectively excited, and satisfactory resonance characteristics can be obtained. More preferably, d/p is about 0.24 or smaller, for example, and in this case, more satisfactory resonance characteristics can be obtained.

In the acoustic wave device 1, since the above-described configuration is provided, even when the number of pairs of the electrodes 3 and 4 is reduced to reduce the size, a Q factor is less likely to be decreased. The reason is that a propagation loss is small even when the number of electrode fingers in reflectors on both sides is reduced. In addition, the number of electrode fingers can be reduced by using the bulk wave in the thickness shear mode. A difference between a Lamb wave used for the acoustic wave device and the bulk wave in the thickness shear mode will be described with reference to FIGS. 25A and 25B.

FIG. 25A is a schematic elevational cross-sectional view for describing the Lamb wave that propagates through the piezoelectric film of the acoustic wave device as disclosed in Japanese Unexamined Patent Application Publication No. 2012-257019. Here, the wave propagates through a piezoelectric film 201 as indicated by an arrow. Here, in the piezoelectric film 201, a first main surface 201a and a second main surface 201b face each other, and the thickness direction connecting the first main surface 201a and the second main surface 201b is a Z-direction. An X-direction is a direction in which the electrode fingers of the IDT electrodes are aligned. As shown in FIG. 25A, in the Lamb wave, the wave propagates in the X-direction as shown in the drawing. Since the wave is a plate wave, the piezoelectric film 201 vibrates as a whole. Since the wave propagates in the X-direction, the reflectors are disposed on both sides to obtain the resonance characteristics. Therefore, the propagation loss of the wave occurs, and the Q factor is decreased when the size is reduced, that is, when the number of pairs of the electrode fingers is reduced.

In contrast, as shown in FIG. 25B, in the acoustic wave device 1, since vibration displacement occurs in a thickness shear direction, the waves mostly propagate and resonate in a direction connecting the first main surface 2a and the second main surface 2b of the piezoelectric layer 2, that is, the Z-direction. That is, an X-direction component of the wave is significantly smaller than a Z-direction component. In addition, since the resonance characteristics are obtained by the propagation of the wave in the Z-direction, the propagation loss is less likely to occur even when the number of the electrode fingers of the reflector is reduced. Therefore, even when the number of pairs of the electrode pairs including the electrodes 3 and 4 is reduced to reduce the size, the Q factor is less likely to be decreased.

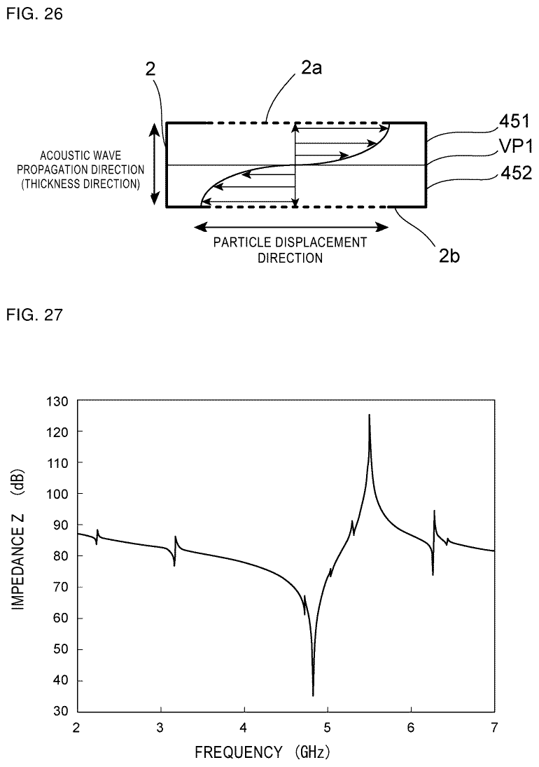

As shown in FIG. 26, amplitude directions of the bulk waves in the thickness shear mode are opposite to each other between a first region 451 included in the excitation region C of the piezoelectric layer 2 and a second region 452 included in the excitation region C. FIG. 26 schematically shows the bulk waves when a voltage is applied between the electrodes 3 and 4 such that the electrode 4 has a higher potential than the electrode 3. The first region 451 is a region of the excitation region C between a virtual plane VP1 orthogonal to the thickness direction of the piezoelectric layer 2 and bisecting the piezoelectric layer 2, and the first main surface 2a. The second region 452 is a region of the excitation region C between the virtual plane VP1 and the second main surface 2b.

As described above, in the acoustic wave device 1, although at least the pair of electrodes including the electrodes 3 and 4 are disposed, the waves do not propagate in the X-direction. Therefore, the number of pairs of the electrode pair including the electrodes 3 and 4 does not need to be the plurality of pairs. That is, at least the pair of electrodes may be provided.

For example, the electrode 3 is the electrode connected to the hot potential, and the electrode 4 is the electrode connected to the ground potential. The electrode 3 may be connected to the ground potential, and the electrode 4 may be connected to the hot potential. In the acoustic wave device 1, as described above, at least the pair of electrodes are the electrodes connected to the hot potential or the electrodes connected to the ground potential, and a floating electrode is not provided.

FIG. 27 is a diagram showing the resonance characteristics of the acoustic wave device shown in FIG. 24. Non-limiting examples of design parameters of the acoustic wave device 1 having the resonance characteristics are as follows.
Piezoelectric layer 2: LiNbO₃ with Euler angles (0°, 0°, 90°), thickness=400 nm.

When viewed in the direction orthogonal to the length direction of the electrodes 3 and 4, the length of the region in which the electrodes 3 and 4 overlap each other, that is, the length of the excitation region C=40 μm, the number of pairs of the electrodes including the electrodes 3 and 4=21 pairs, the center distance between the electrodes=3 μm, the width of the electrodes 3 and 4=500 nm, and d/p=0.133.
Insulating layer 7: silicon oxide film including the thickness of 1 μm.
Support 8: Si.

The length of the excitation region C is the dimension in the length direction of the electrodes 3 and 4 of the excitation region C.

In the acoustic wave device 1, an electrode-to-electrode distance of the electrode pair including the electrodes 3 and 4 is set to be equal in all of the plurality of pairs. That is, the electrodes 3 and 4 are disposed at an equal pitch.

As is clear from FIG. 27, satisfactory resonance characteristics with the fractional bandwidth of about 12.5%, for example, are obtained regardless of the absence of the reflector.

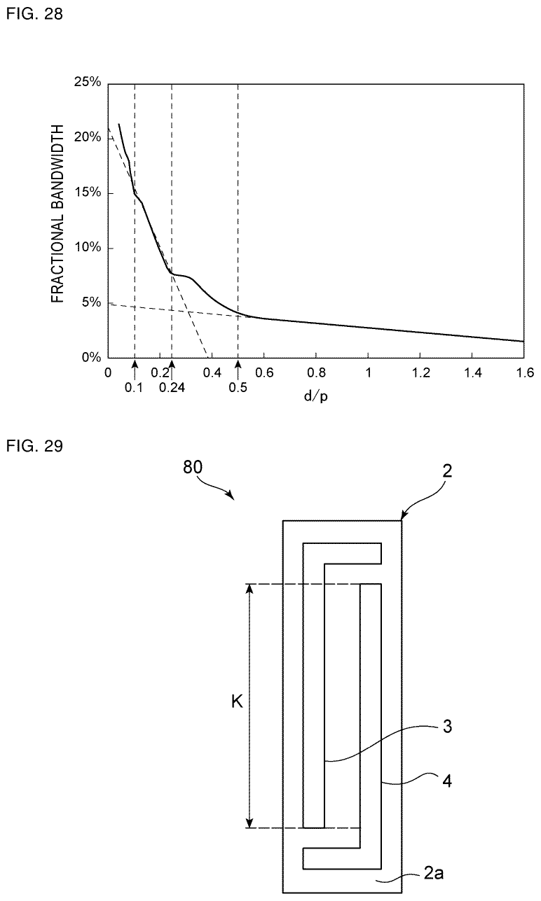

Incidentally, when the thickness of the piezoelectric layer 2 is defined as d and the center-to-center distance between the electrodes 3 and 4 is defined as p, in the acoustic wave device 1, as described above, d/p is about 0.5 or smaller, and is more preferably about 0.24 or smaller, for example. This configuration will be described with reference to FIG. 28.

The plurality of acoustic wave devices are obtained by changing d/p as in the acoustic wave device that obtains the resonance characteristics shown in FIG. 27. FIG. 28 is a diagram showing a relationship between d/p and a fractional bandwidth as the resonator of the acoustic wave device.

As is clear from FIG. 28, when d/p>about 0.5, for example, the fractional bandwidth is smaller than about 5% even when d/p is adjusted. In contrast, in a case of d/p>about 0.5, for example, when d/p is changed within this range, the fractional bandwidth can be about 5% or larger, that is, a resonator having a high coupling coefficient can be formed. In addition, when d/p is about 0.24 or smaller, for example, the fractional bandwidth can be increased to about 7% or larger. In addition, when d/p is adjusted within this range, a resonator having a wider fractional bandwidth can be obtained, and a resonator having a higher coupling coefficient can be realized. Therefore, it can be understood that the resonator using the bulk wave in the thickness shear mode and having the high coupling coefficient can be formed by adjusting d/p to about 0.5 or smaller, for example.

FIG. 29 is a plan view of an acoustic wave device using a bulk wave in a thickness shear mode. In an acoustic wave device 80, the pair of electrodes including the electrode 3 and electrode 4 are provided on the first main surface 2a of the piezoelectric layer 2. K in FIG. 29 is an intersecting width. As described above, in the acoustic wave device according to the present invention, the number of pairs of the electrodes may be one pair. Even in this case, when d/p is about 0.5 or smaller, for example, the bulk wave in the thickness shear mode can be effectively excited.

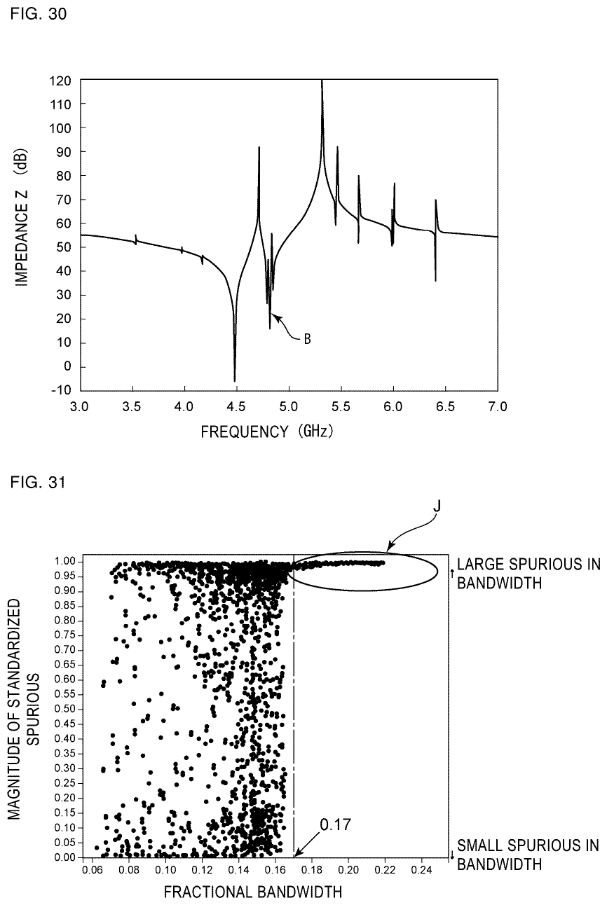

In the acoustic wave device 1, preferably, it is desirable that a metallization ratio MR of any adjacent electrodes 3 and 4 in the plurality of electrodes 3 and 4 to the excitation region C which is the region in which the adjacent electrodes 3 and 4 overlap each other when viewed in the facing direction satisfies MR≤about 1.75 (d/p)+0.075, for example. In this case, the spurious can be effectively reduced. This configuration will be described with reference to FIGS. 30 and 31. FIG. 30 is a reference view showing an example of the resonance characteristics of the acoustic wave device 1. The spurious indicated by an arrow B appears between the resonant frequency and the anti-resonant frequency. In the example, d/p=about 0.08 is set, and the Euler angles (0°, 0°, 90°) of LiNbO₃ are set, for example. In addition, the metallization ratio MR=about 0.35 is set, for example.

The metallization ratio MR will be described with reference to FIG. 23B. In the electrode structure of FIG. 23B, in a case of focusing on the pair of electrodes 3 and 4, only the pair of electrodes 3 and 4 are provided. In this case, a portion surrounded by one-dot chain line is the excitation region C. The excitation region C is a region overlapping the electrode 4 in the electrode 3 when the electrode 3 and the electrode 4 are viewed in the direction orthogonal to the length direction of the electrodes 3 and 4, that is, in the facing direction, a region overlapping the electrode 3 in the electrode 4, and a region in which the electrode 3 and the electrode 4 overlap each other in the region between the electrode 3 and the electrode 4. An area of the electrodes 3 and 4 inside the excitation region C with respect to an area of the excitation region C is the metallization ratio MR. That is, the metallization ratio MR is a ratio of an area of the metallization portion with respect to an area of the excitation region C.

When the plurality of pairs of electrodes are provided, a ratio of the metallization portion included in the entire excitation region with respect to a total area of the excitation region may be MR.

FIG. 31 is a diagram showing a relationship between the fractional bandwidth and a phase rotation amount of the impedance of the spurious standardized at 180 degrees as a magnitude of the spurious when a large number of acoustic wave resonators are configured according to an example embodiment of the acoustic wave device 1. The fractional bandwidth is adjusted by changing the film thickness of the piezoelectric layer and the dimensions of the electrodes. In addition, FIG. 31 shows results when the piezoelectric layer formed of Z-cut LiNbO₃i is used, but shows the same tendency when the piezoelectric layer having other cut-angles is used.

In a region surrounded by an ellipse J in FIG. 31, the spurious is as large as about 1.0, for example. As is clear from FIG. 31, when the fractional bandwidth exceeds about 0.17, that is, exceeds about 17%, for example, a large spurious with a spurious level of 1 or larger appears inside a pass band even when the parameters forming the fractional bandwidth are changed. That is, as in the resonance characteristics shown in FIG. 30, a large spurious indicated by an arrow B appears inside the band. Therefore, the fractional bandwidth is preferably about 17% or smaller, for example. In this case, the spurious can be reduced by adjusting the film thickness of the piezoelectric layer 2 and the dimensions of the electrodes 3 and 4.

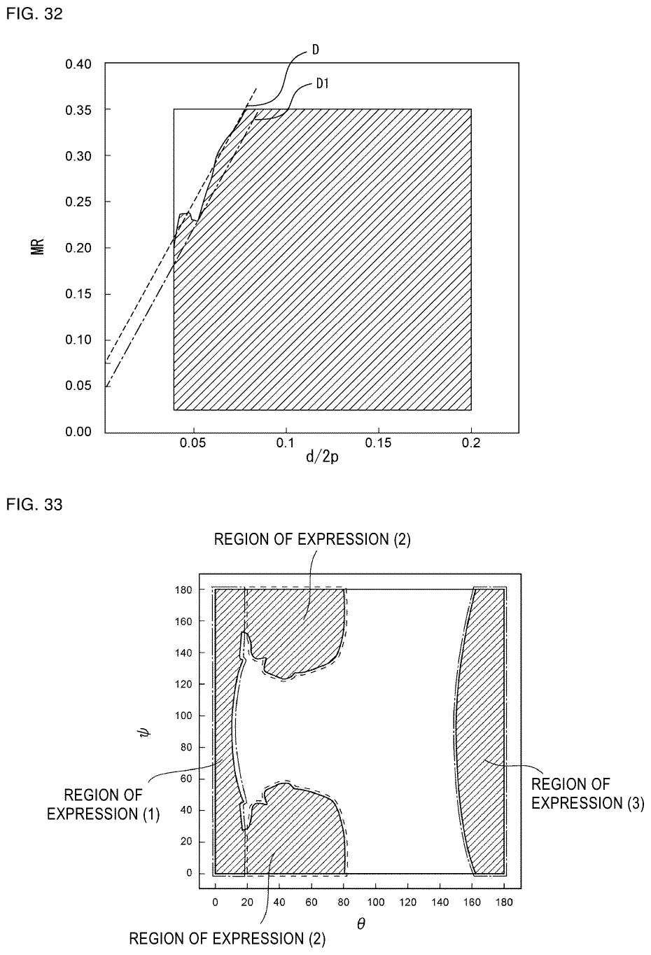

FIG. 32 is a diagram showing a relationship between d/2p, the metallization ratio MR, and the fractional bandwidth. In the acoustic wave device described above, various acoustic wave devices having different d/2p and MR are configured, and the fractional bandwidth is measured. A hatched portion on a right side of a broken line D in FIG. 32 is a region in which the fractional bandwidth is about 17% or smaller, for example. A boundary between the hatched region and a non-hatched region is expressed by MR=about 3.5 (d/2p)+0.075, for example. That is, MR=about 1.75 (d/p)+0.075, for example. Therefore, preferably, MR≤about 1.75 (d/p)+0.075, for example. In this case, it is easy to set the fractional bandwidth to about 17% or smaller, for example. It is more preferable to set a region on a right side of MR=about 3.5 (d/2p)+0.05, for example, indicated by a one-dot chain line D1 in FIG. 32. That is, in a case of MR≤about 1.75 (d/p)+0.05, the fractional bandwidth can be reliably set to about 17% or smaller, for example.

FIG. 33 is a diagram showing a map of the fractional bandwidth with respect to Euler angles (0°, θ, ψ) of LiNbO₃ when d/p is infinitely close to 0. A hatched portion in FIG. 33 is a region in which the fractional bandwidth of at least about 5% or larger is obtained, for example, and when a range of the region is approximated, the range is represented by Expression (1), Expression (2), and Expression (3).

(0°±10°,0° to 20°, any ψ) Expression (1)

(0°±10°,20° to 80°,0° to 60° (1−(θ−50)²/900)^{1/2}) or (0°±10°,20° to 80°,[180°−60° (1−(θ−50)²/900)^{1/2}] to 180°) Expression (2)

(0°±10°,[180°−30° (1−(ψ−90)²/8100)^{1/2}] to 180°, any ψ) Expression (3)

Therefore, in a case of the Euler angle range of Expression (1), Expression (2), or Expression (3), it is preferable since the fractional bandwidth can be sufficiently widened. The same applies to a case where the piezoelectric layer 2 is the lithium tantalate layer.

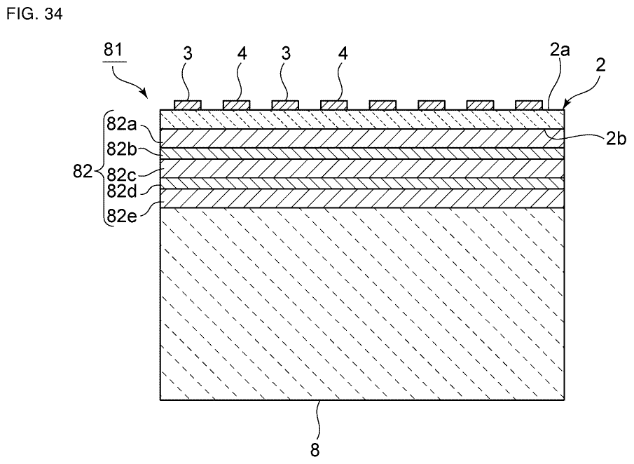

FIG. 34 is an elevational cross-sectional view of an acoustic wave device including an acoustic multilayer film.

In an acoustic wave device 81, an acoustic multilayer film 82 is laminated on the second main surface 2b of the piezoelectric layer 2. The acoustic multilayer film 82 has a multilayer structure of low acoustic impedance layers 82a, 82c, and 82e having a relatively low acoustic impedance and high acoustic impedance layers 82b and 82d having a relatively high acoustic impedance. When the acoustic multilayer film 82 is used, the bulk wave in the thickness shear mode can be confined in the piezoelectric layer 2 without using the cavity portion 9 in the acoustic wave device 1. In the acoustic wave device 81 as well, the resonance characteristics based on the bulk wave in the thickness shear mode can be obtained by setting d/p to about 0.5 or smaller, for example. In the acoustic multilayer film 82, the number of laminated layers of the low acoustic impedance layers 82a, 82c, and 82e and the high acoustic impedance layers 82b and 82d is not particularly limited. At least one layer of the high acoustic impedance layers 82b and 82d may be disposed on a side farther from the piezoelectric layer 2 than the low acoustic impedance layers 82a, 82c, and 82e.

The low acoustic impedance layers 82a, 82c, and 82e and the high acoustic impedance layers 82b and 82d can be formed of an appropriate material as long as the above-described relationship of the acoustic impedance is satisfied. Examples of the materials of the low acoustic impedance layers 82a, 82c, and 82e include silicon oxide, silicon oxynitride, and the like. In addition, examples of the materials of the high acoustic impedance layers 82b and 82d include alumina, silicon nitride, metal, and the like.

In the acoustic wave devices according to the first to seventh example embodiments and each of the modification examples, for example, the acoustic multilayer film 82 shown in FIG. 34 may be provided as an acoustic reflection film between the support and the piezoelectric layer serving as the piezoelectric film. Specifically, the support and the piezoelectric film may be disposed such that at least a portion of the support and at least a portion of the piezoelectric film face each other across the acoustic multilayer film 82. In this case, in the acoustic multilayer film 82, the low acoustic impedance layer and the high acoustic impedance layer may be alternately laminated. The acoustic multilayer film 82 may be the acoustic reflection portion in the acoustic wave device.

In the acoustic wave devices according to the first to seventh example embodiments and each of the modification examples that use the bulk wave in the thickness shear mode, as described above, d/p is preferably about 0.5 or smaller, and more preferably about 0.24 or smaller, for example. In this manner, more satisfactory resonance characteristics can be obtained. Further, in the excitation regions in the acoustic wave devices according to the first to seventh example embodiments and each of the modification examples that use the bulk wave in the thickness shear mode, as described above, preferably, MR≤about 1.75 (d/p)+0.075 is satisfied, for example. In this case, the spurious can be more reliably suppressed.

In the acoustic wave devices of the first to seventh example embodiments and each of the modification examples which use the bulk wave in the thickness shear mode, it is preferable that the piezoelectric layer is a lithium niobate layer. In addition, it is preferable that the Euler angles (o, 0, y) of the lithium niobate of the piezoelectric layer are in the ranges of Expression (1), Expression (2), or Expression (3). In this case, the fractional bandwidth can be sufficiently widened.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including:
a support including a support substrate; and
a piezoelectric film provided on the support and including a piezoelectric layer including lithium niobate; and
an IDT electrode provided on the piezoelectric layer and including a pair of busbars and a plurality of electrode fingers;
wherein an acoustic reflection portion is provided at a position in the support overlapping the IDT electrode in plan view in a multilayer direction of the support and the piezoelectric film;
when a thickness of the piezoelectric film is defined as d and a center-to-center distance between the electrode fingers adjacent to each other is defined as p, d/p is about 0.5 or smaller;
some electrode fingers of the plurality of electrode fingers are connected to one of the busbars of the IDT electrode, remaining electrode fingers of the plurality of electrode fingers are connected to an other of the busbars, and the plurality of electrode fingers connected to the busbar and the plurality of electrode fingers connected to the other busbar are interdigitated with each other;
when a direction in which the plurality of electrode fingers extend is defined as an electrode finger extending direction, and a direction orthogonal to the electrode finger extending direction is defined as an electrode finger orthogonal direction, when viewed in the electrode finger orthogonal direction, a region in which the electrode fingers adjacent to each other overlap each other is an intersecting region, a region located between the intersecting region and the pair of busbars is a pair of gap regions, and the intersecting region includes a central region and a pair of edge regions extending across the central region in the electrode finger extending direction; and
the acoustic wave device further comprises:
a strip-shaped mass addition film provided in at least one gap region of the pair of gap regions and continuously extending to overlap the plurality of electrode fingers and a region between the electrode fingers in plan view; and
a plurality of granular mass addition films extending over the gap region in which the strip-shaped mass addition film is provided and one of the edge regions adjacent to the gap region and not overlapping at least a portion in at least a region between the electrode fingers adjacent to each other in plan view.

2. The acoustic wave device according to claim 1,
wherein each of the plurality of granular mass addition films overlaps one or less of the electrode fingers in plan view.

3. The acoustic wave device according to claim 1, wherein
the strip-shaped mass addition film includes a first strip-shaped mass addition film provided in one of the gap regions and a second strip-shaped mass addition film provided in an other of the gap regions; and
the plurality of granular mass addition films include a plurality of first granular mass addition films extending over the gap region in which the first strip-shaped mass addition film is provided and one of the edge regions adjacent to the gap region, and a plurality of second granular mass addition films extending over the other gap region in which the second strip-shaped mass addition film is provided and an other of the edge regions adjacent to the other gap region.

4. The acoustic wave device according to claim 1, wherein
the plurality of granular mass addition films include the granular mass addition film including a portion laminated with the electrode finger; and
in a portion where the granular mass addition film and the electrode finger are laminated, the piezoelectric layer, the electrode finger, and the granular mass addition film are laminated in this order.

5. The acoustic wave device according to claim 1, wherein
the plurality of granular mass addition films include the granular mass addition film including a portion laminated with the electrode finger; and
in a portion where the granular mass addition film and the electrode finger are laminated, the piezoelectric layer, the granular mass addition film, and the electrode finger are laminated in this order.

6. The acoustic wave device according to claim 4, wherein the granular mass addition film including the portion laminated with the electrode finger includes a portion laminated with a tip portion of the electrode finger.

7. The acoustic wave device according to claim 1, wherein the plurality of granular mass addition films include the granular mass addition film that surrounds a tip portion of the electrode finger in three directions in plan view.

8. The acoustic wave device according to claim 1, wherein
the strip-shaped mass addition film includes a first strip-shaped mass addition film provided in one of the gap regions;
the plurality of granular mass addition films include a plurality of first granular mass addition films extending over the gap region in which the first strip-shaped mass addition film is provided and one of the edge regions adjacent to the gap region;
a plurality of electrode finger pair regions are provided, each of the plurality of electrode finger pair regions being a region including only a pair of the electrode fingers connected to the busbars which are different from each other of the plurality of electrode fingers; and
the plurality of electrode finger pair regions include at least one of the electrode finger pair regions in which a total area of the first strip-shaped mass addition film and the first granular mass addition film is different from a total area of another of the electrode finger pair regions.

9. The acoustic wave device according to claim 1, wherein the strip-shaped mass addition film provided in at least one of the pair of gap regions extends from the gap region to a portion overlapping the busbar adjacent to the gap region in plan view.

10. The acoustic wave device according to claim 1, wherein the strip-shaped mass addition film and the plurality of granular mass addition films which are provided in a same gap region of the gap regions are integrally formed of a same material.

11. The acoustic wave device according to claim 1, wherein the strip-shaped mass addition film and the plurality of granular mass addition films which are located in a same gap region of the gap regions are separate and independent from each other, and the strip-shaped mass addition film and the plurality of granular mass addition films are not in contact with each other.

12. The acoustic wave device according to claim 1, further comprising a dielectric film provided on the piezoelectric layer to cover the IDT electrode.

13. The acoustic wave device according to claim 12, wherein the dielectric film includes silicon oxide.

14. The acoustic wave device according to claim 1, wherein the strip-shaped mass addition film and the plurality of granular mass addition films include silicon oxide, tantalum oxide, niobium oxide, tungsten oxide, or hafnium oxide.

15. The acoustic wave device according to claim 1, wherein d/p is about 0.24 or smaller.

16. The acoustic wave device according to claim 1, wherein an excitation region is a region in which the electrode fingers adjacent to each other overlap each other when viewed in the electrode finger orthogonal direction, and is a center-to-center region in the electrode finger orthogonal direction of the adjacent electrode fingers; and
when a metallization ratio of the plurality of electrode fingers to the excitation region is defined as MR, MR≤about 1.75 (d/p)+0.075 is satisfied.

17. The acoustic wave device according to claim 1, wherein
Euler angles (φ, θ, ψ) of lithium niobate of the piezoelectric layer are within a range of Expression (1), Expression (2), or Expression (3):
(0°±10°,0° to 20°, any ψ) Expression (1)
(0°±10°,20° to 80°,0° to 60° (1−(θ−50)²/900)^{1/2}) or (0°±10°,20° to 80°,[180°−60° (1−(θ−50)²/900)^{1/2}] to 180°) Expression (2)
(0°±10°,[180°−30° (1−(θ−90)²/8100)^{1/2}] to 180°, any 4) Expression (3).

18. The acoustic wave device according to claim 1, wherein the acoustic reflection portion includes a cavity portion, and the support and the piezoelectric film are positioned such that a portion of the support and a portion of the piezoelectric film face each other across the cavity portion.

19. The acoustic wave device according to claim 1, wherein the acoustic reflection portion includes an acoustic reflection film including a high acoustic impedance layer having a relatively high acoustic impedance and a low acoustic impedance layer having a relatively low acoustic impedance, and the support and the piezoelectric film are positioned such that at least a portion of the support and at least a portion of the piezoelectric film face each other across the acoustic reflection film.

20. A filter device comprising:
a plurality of acoustic wave resonators including at least one series arm resonator and at least one parallel arm resonator; wherein
at least one of the acoustic wave resonators of the series arm resonator and the parallel arm resonator is the acoustic wave device according to claim 1.

21. The filter device according to claim 20, wherein
the series arm resonator and the parallel arm resonator include at least one first acoustic wave resonator and at least one second acoustic wave resonator;
the first acoustic wave resonator is the acoustic wave device; and
the second acoustic wave resonator includes a piezoelectric substrate and an IDT electrode provided on the piezoelectric substrate and including a pair of busbars and a plurality of electrode fingers, and does not include a mass addition film corresponding to the strip-shaped mass addition film or the granular mass addition film of the first acoustic wave resonator.

22. The filter device according to claim 20, wherein
the series arm resonator and the parallel arm resonator include at least one first acoustic wave resonator and at least one third acoustic wave resonator;
the first acoustic wave resonator is the acoustic wave device;
the third acoustic wave resonator includes a piezoelectric substrate and an IDT electrode provided on the piezoelectric substrate and including a pair of busbars and a plurality of electrode fingers, and does not include a mass addition film corresponding to the granular mass addition film of the first acoustic wave resonator;
in the third acoustic wave resonator, when the IDT electrode is viewed in a direction orthogonal to a direction in which the plurality of electrode fingers extend, a region in which the electrode fingers adjacent to each other overlap each other is an intersecting region, and a region located between the intersecting region and the pair of busbars of the IDT electrode is a pair of gap regions; and
the third acoustic wave resonator includes a strip-shaped mass addition film separate from the first acoustic wave resonator, and in the third acoustic wave resonator, the strip-shaped mass addition film is provided in at least one gap region of the pair of gap regions, and is not provided in the intersecting region, and the strip-shaped mass addition film continuously extends to overlap the plurality of electrode fingers and a region between the electrode fingers in plan view.

23. The filter device according to claim 20, wherein
the series arm resonator and the parallel arm resonator include at least one first acoustic wave resonator and at least one fourth acoustic wave resonator;
the first acoustic wave resonator is the acoustic wave device;
the fourth acoustic wave resonator includes a piezoelectric substrate and an IDT electrode provided on the piezoelectric substrate and including a pair of busbars and a plurality of electrode fingers, and does not include a mass addition film corresponding to the strip-shaped mass addition film of the first acoustic wave resonator;
in the fourth acoustic wave resonator, when the IDT electrode is viewed in a direction orthogonal to a direction in which the plurality of electrode fingers extend, a region in which the electrode fingers adjacent to each other overlap each other is an intersecting region, a region located between the intersecting region and the pair of busbars of the IDT electrode is a pair of gap regions, and the intersecting region includes a central region and a pair of edge regions extending across the central region in the electrode finger extending direction; and
the fourth acoustic wave resonator includes a plurality of granular mass addition films separate from the first acoustic wave resonator, and in the fourth acoustic wave resonator, the plurality of granular mass addition films extend over at least one gap region of the pair of gap regions and one of the edge regions adjacent to the gap region, and overlap one or less of the electrode fingers in plan view.

24. The filter device according to claim 20, wherein
the series arm resonator and the parallel arm resonator include at least one first acoustic wave resonator and at least one fifth acoustic wave resonator;
the first acoustic wave resonator is the acoustic wave device;
the fifth acoustic wave resonator includes a piezoelectric substrate and an IDT electrode provided on the piezoelectric substrate and including a pair of busbars and a plurality of electrode fingers, and does not include a mass addition film corresponding to the granular mass addition film of the first acoustic wave resonator;
in the fifth acoustic wave resonator, when the IDT electrode is viewed in a direction orthogonal to a direction in which the plurality of electrode fingers extend, a region in which the electrode fingers adjacent to each other overlap each other is an intersecting region, a region located between the intersecting region and the pair of busbars of the IDT electrode is a pair of gap regions, and the intersecting region includes a central region and a pair of edge regions extending across the central region in the direction in which the plurality of electrode fingers extend; and
the fifth acoustic wave resonator includes a strip-shaped mass addition film separate and independent from the first acoustic wave resonator, and in the fifth acoustic wave resonator, the strip-shaped mass addition film extends over at least one gap region of the pair of gap regions and one of the edge regions adjacent to the gap region, and continuously extends to overlap the plurality of electrode fingers and a region between the electrode fingers in plan view.
